(19) United States
(12) Patent Application Publication
(10) Pub. No.: US 2026/0090169 A1
(43) Pub. Date: Mar. 26, 2026

(54) DETECTING DEVICE

(71) Applicant: Japan Display Inc., Tokyo (JP)

(72) Inventors: Masataka IKEDA, Tokyo (JP); Yoshinori AOKI, Tokyo (JP)

(21) Appl. No.: 19/327,210

(22) Filed: Sep. 12, 2025

(30) Foreign Application Priority Data
Sep. 20, 2024 (JP) 2024-163943

(51) Int. Cl. H10H 29/49; H10H 29/32

(52) U.S. Cl. CPC H10H 29/49; H10H 29/32

(57) ABSTRACT

The detecting device includes a photoelectric conversion element electrically connected to a first node, a first transistor including a first oxide semiconductor layer electrically connected between the first node and a second node, a second transistor provided in the same layer as the first oxide semiconductor layer and including a second oxide semiconductor layer connected between the second node and a reset potential line to which a constant voltage is supplied, a first conductive layer stacked under the same layer and electrically connected to a power supply line that supplies a power supply voltage, an electrode layer stacked on the same layer and electrically connected to the second node, and a first capacitance element including a second conductive layer stacked on the electrode layer and electrically connected to the power supply line.

### CROSS-REFERENCE TO RELATED APPLICATIONS

This application claims the benefit of priority to Japanese Patent Application No. 2024-163943 filed on Sep. 20, 2024, the entire contents of which are incorporated herein by reference.

### FIELD

An embodiment of the present invention relates to a detecting device.

### BACKGROUND

In recent years, detecting devices for non-destructively inspecting an object to be inspected have become popular. For example, the detecting device is an X-ray detecting device, a fingerprint detecting device, or the like used in the field of medical technology, the field of transportation technology, or the like.

For example, a detecting device capable of suppressing variation in an output signal is known. A detecting device capable of suppressing variation in an output signal includes a plurality of detection elements (for example, pixels), and each of the plurality of detection elements includes a photoelectric conversion element, a plurality of transistors, and a capacitive element.

### SUMMARY

A detecting device includes a photoelectric conversion element electrically connected to a first node, a first transistor including a first oxide semiconductor layer electrically connected between the first node and a second node, a second transistor including a second oxide semiconductor layer provided in the same layer as the first oxide semiconductor layer and connected between the second node and a reset potential line to which a constant voltage is supplied, and a first capacitance element including a first conductive layer stacked under the same layer as the first oxide semiconductor layer and electrically connected to a power supply line that supplies a power supply voltage, an electrode layer stacked on the same layer as the first oxide semiconductor layer and electrically connected to the second node, and a second conductive layer stacked on the electrode layer and electrically connected to the power supply line.

A detecting device includes a photoelectric conversion element electrically connected to a first node, a first transistor including a first oxide semiconductor layer electrically connected between the first node and a second node, a second transistor including a second oxide semiconductor layer provided in the same layer as the first oxide semiconductor layer and connected between the second node and a reset potential line to which a constant voltage is supplied, and a first capacitance element including a first conductive layer stacked under the same layer as the first oxide semiconductor layer and electrically connected to a power supply line that supplies a power supply voltage, a third oxide semiconductor layer arranged in the same layer as the first oxide semiconductor layer and electrically connected to the second node, and a second conductive layer stacked on the third oxide semiconductor layer and electrically connected to the power supply line.

A detecting device includes a photoelectric conversion element electrically connected to a first node, a first transistor including a first oxide semiconductor layer electrically connected between the first node and a second node, a second transistor provided in the same layer as the first oxide semiconductor layer and including a second oxide semiconductor layer connected between the second node and a reset potential line to which a constant voltage is supplied, a first capacitance element including a first conductive layer stacked on the same layer and electrically connected to a power supply line to which a power supply voltage is supplied, and a second conductive layer stacked on the first conductive layer and electrically connected to the second node, and a second capacitance element including a third conductive layer arranged on the second conductive layer and electrically connected to a reference potential line to which a reference voltage is supplied.

### BRIEF DESCRIPTION OF DRAWINGS

FIG. 1 is a plan view showing a configuration of a detecting device according to a first embodiment of the present invention.

FIG. 2 is a plan view showing the configuration of the detecting device according to the first embodiment of the present invention.

FIG. 3 is a circuit diagram showing a pixel circuit according to the first embodiment of the present invention.

FIG. 4 is an end view showing an example of an end face structure of a pixel according to the first embodiment of the present invention.

FIG. 5 is a plan view showing a layout of a part of the pixels according to the first embodiment of the present invention.

FIG. 6 is a plan view showing a layout of a part of the pixels according to the first embodiment of the present invention.

FIG. 7 is a plan view showing a layout of a part of the pixels according to the first embodiment of the present invention.

FIG. 8 is a plan view showing a layout of a part of the pixels according to the first embodiment of the present invention.

FIG. 9 is a plan view showing a layout of a part of the pixels according to the first embodiment of the present invention.

FIG. 10 is an end view showing an exemplary end face construction cut along A1-A2 in the layout of a part of the pixels shown in FIG. 5.

FIG. 11 is an end view showing an exemplary end face construction cut along B1-B2 in the layout of a part of the pixels shown in FIG. 5.

FIG. 12 is a plan view showing a layout of a part of pixels according to a second embodiment of the present invention.

FIG. 13 is a plan view showing a layout of a part of the pixels according to the second embodiment of the present invention.

FIG. 14 is a plan view showing a layout of a part of the pixels according to the second embodiment of the present invention.

FIG. 15 is a plan view showing a layout of a part of the pixels according to the second embodiment of the present invention.

FIG. 16 is a plan view showing a layout of a part of the pixels according to the second embodiment of the present invention.

FIG. 17 is an end view showing an exemplary end face construction cut along C1-C2 in the layout of a part of the pixels shown in FIG. 12.

FIG. 18 is an end view showing an exemplary end face construction cut along E1-E2 in the layout of a part of the pixels shown in FIG. 12.

FIG. 19 is a circuit diagram showing a pixel circuit according to a third embodiment of the present invention.

FIG. 20 is a plan view showing a layout of a part of pixels according to the third embodiment of the present invention.

FIG. 21 is a plan view showing a layout of a part of the pixels according to the third embodiment of the present invention.

FIG. 22 is a plan view showing a layout of a part of the pixels according to the third embodiment of the present invention.

FIG. 23 is a plan view showing a layout of a part of the pixels according to the third embodiment of the present invention.

FIG. 24 is a plan view showing a layout of a part of the pixels according to the third embodiment of the present invention.

FIG. 25 is a plan view showing a layout of a part of the pixels according to the third embodiment of the present invention.

FIG. 26 is a plan view showing a layout of a part of the pixels according to the third embodiment of the present invention.

FIG. 27 is a plan view showing a layout of a part of the pixels according to the third embodiment of the present invention.

FIG. 28 is a plan view showing a layout of a part of the pixels according to the third embodiment of the present invention.

FIG. 29 is an end view showing an exemplary end face construction cut along F1-F2 in the layout of a part of the pixels shown in FIG. 20.

FIG. 30 is an end view showing an exemplary end face construction cut along G1-G2 in the layout of a part of the pixels shown in FIG. 20.

FIG. 31 is an end view showing an exemplary end face construction cut along H1-H2 in the layout of a part of the pixels shown in FIG. 21.

### DESCRIPTION OF EMBODIMENTS

Hereinafter, embodiments of the present invention will be described with reference to the drawings and the like. However, the present invention can be implemented in many different aspects, and should not be construed as being limited to the description of the embodiments exemplified below. Further, in order to make the description clearer, the drawings may be schematically represented with respect to the width, thickness, shape, configuration, and the like of each part as compared with the actual embodiment, but the drawings are merely examples, and do not limit the interpretation of the present invention. It should be noted that the terms “first” and “second” attached to each element are convenient labels used to distinguish each element, and do not have any further meaning unless otherwise described.

Also, in the specification of the present application, the expression “a includes A, B, or C,” “α includes any of A, B, or C,” “a includes one selected from the group comprising A, B, and C,” and the like does not exclude cases where a includes a plurality of combinations of A to C unless otherwise specified. Furthermore, these expressions do not exclude the case where a includes other elements.

As used herein, a first direction D1 intersects a second direction D2, and a third direction D3 intersects the first direction D1 and the second direction D2 (a plane D1D2). For example, the first direction D1, the second direction D2, and the third direction D3 correspond to an X direction (an x direction), a Y direction (a y direction), and a Z direction (a z direction). The first direction D1 may be orthogonal to the second direction D2, the first direction D1 may be orthogonal to the third direction D3, and the second direction D2 may be orthogonal to the third direction D3.

Where the terms parallel, same, and matched are used herein, errors within the scope of the design may be included in parallel, same, and matched.

For example, a detecting device according to one embodiment of the present invention includes a device that detects biological information such as a fingerprint, a device that detects X-rays, a solid-state imaging device, and the like. For example, the solid-state imaging device is a CMOS (Complementary Metal Oxide Semiconductor) image sensor, a CCD (Charge Coupled Device) image sensor, or the like. For example, the solid-state imaging device according to one embodiment of the present disclosure is the CMOS image sensor. As an example, although one of the embodiments of the present invention is a solid-state imaging device, the present invention is not limited to the solid-state imaging device, it is naturally applicable to a detecting device for detecting biological information such as a fingerprint sensor and a detecting device for detecting X-rays. Further, the imaging data to be described later may be referred to as detection data.

### BACKGROUND OF INVENTION

For example, development has been made to provide a solid-state imaging device with high long-term reliability.

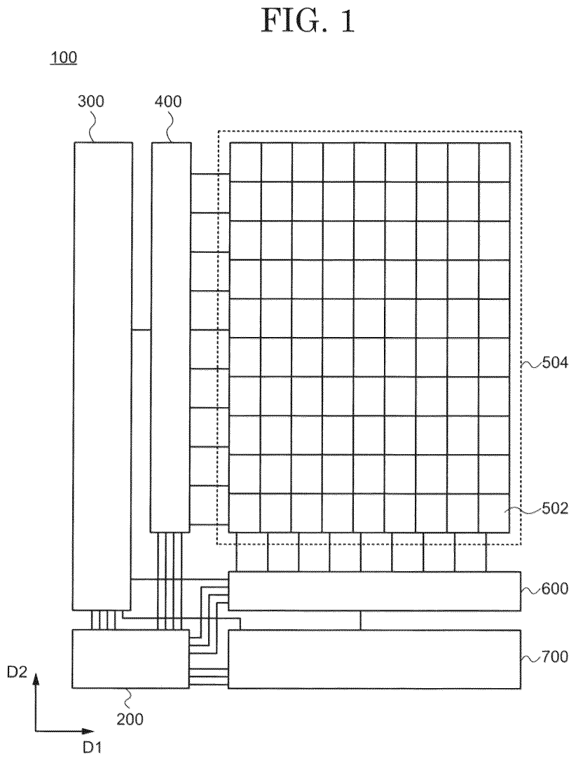

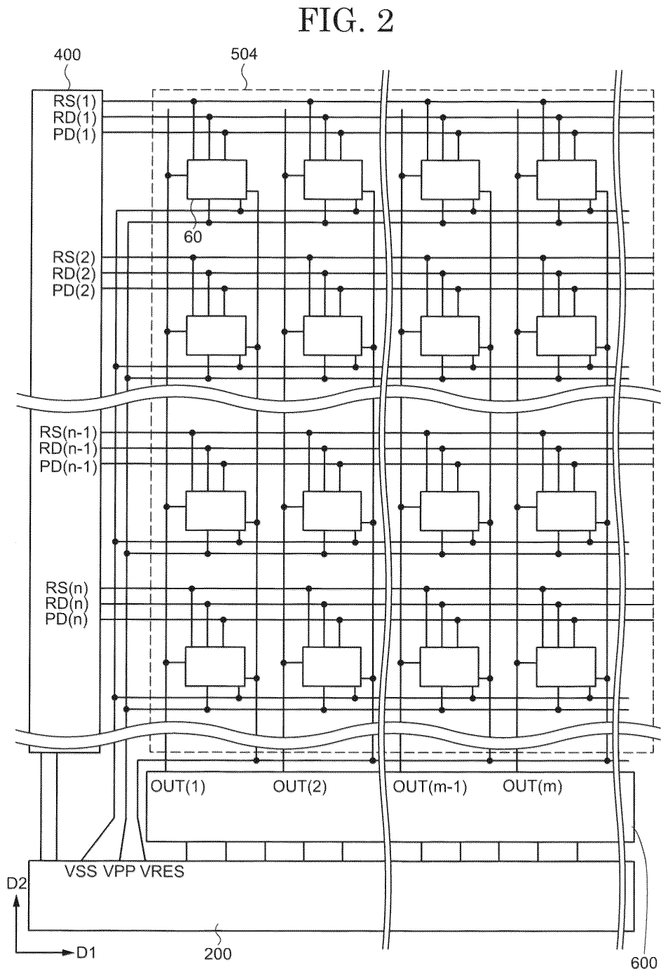

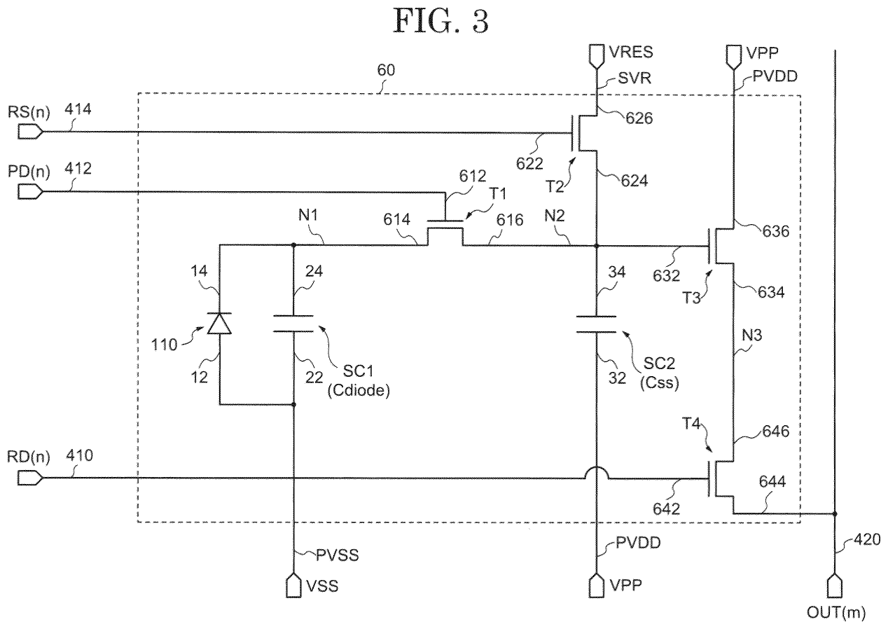

In general, a solid-state imaging device includes a plurality of pixels, and each of the plurality of pixels includes a photoelectric conversion element, a plurality of transistors, and a capacitive element. A data transfer transistor T1 (see FIG. 3) has a function of conducting a node N1 (see FIG. 3) and a node N2 (see FIG. 3), and supplying a current based on photovoltaic power generated by light received by a photoelectric conversion element 110 (see FIG. 1 and FIG. 2) along with exposure of a pixel 502 (see FIG. 1 and FIG. 2) from the node N1 (see FIG. 3) to the node N2 (see FIG. 3). The photoelectric conversion element 110 is electrically connected to the node N1, and a capacitive element SC2 is electrically connected to the node N2. For example, in order to efficiently transmit a current based on the photovoltaic power generated by the light received by the photoelectric conversion element 110 along with the exposure of the pixel 502 from the node N1 to the node N2, it is essential to reduce influences of parasitic capacitance between the respective elements (nodes). For example, in order to reduce the influences of the parasitic capacitance, it is essential to increase capacitance of the capacitive element SC2 electrically connected to the node N2 and to reduce parasitic capacitance due to coupling between the node N1 and the node N2.

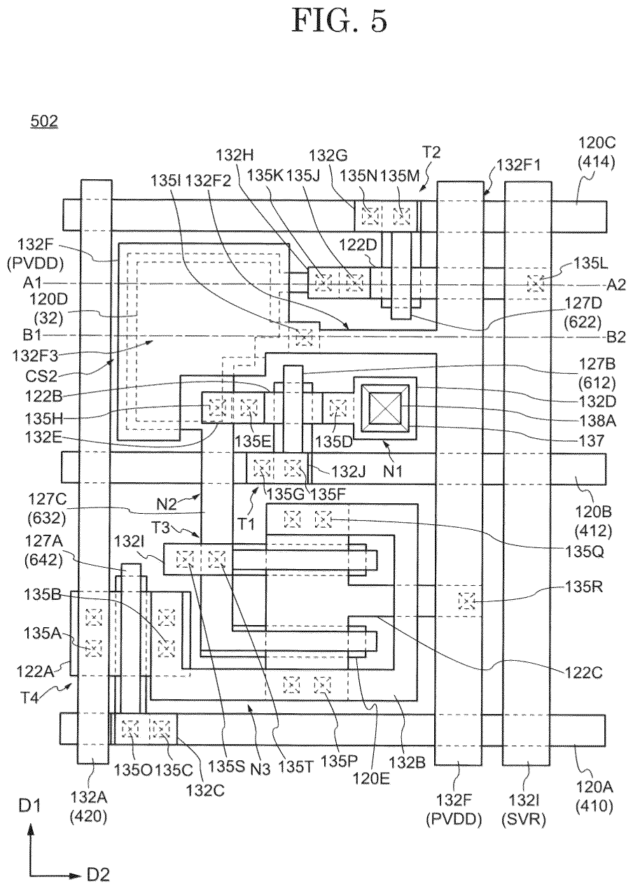

For example, as shown in FIG. 3 or FIG. 5, the solid-state imaging device which is one of the embodiments of the present invention includes the photoelectric conversion element 110 electrically connected to the node N1, the data transfer transistor T1 including an oxide semiconductor layer 122B electrically connected between the node N1 and the node N2, a reset transistor T2 including an oxide semiconductor layer 122D provided in the same layer as the oxide semiconductor layer 122B and connected between the node N2 and the reset potential line SVR to which the reset potential VRES is supplied, a conductive layer 120D stacked on the same layer and electrically connected to the node N2, a gate electrode 127C stacked on the same layer and electrically connected with the node N2, and a first capacitive element including a conductive layer 132F stacked on the gate electrode 127C and electrically connected to a drive power supply line PVDD.

As a result, the solid-state imaging device according to one embodiment of the present disclosure can suppress the influence of the parasitic capacitance between the respective elements (nodes) by increasing the capacitance of the capacitive element SC2 electrically connected to the node N2 and reducing the parasitic capacitance due to the coupling between the node N1 and the node N2. By suppressing the influence of the parasitic capacitance between the elements (each node), the long-term reliability of the solid-state imaging device is improved.

In the following embodiments, a solid-state imaging device that is one of the embodiments of the present invention will be described in detail.

### 1. First Embodiment

### [1-1. Configuration of Solid-State Imaging Device 100]

An overview of a solid-state imaging device 100 will be described with reference to FIG. 1 and FIG. 2. FIG. 1 and FIG. 2 are plan views showing a configuration of the solid-state imaging device 100.

As shown in FIG. 1, the solid-state imaging device 100 includes a power supply circuit 200, a drive timing control circuit 300, a row selection circuit 400, a pixel section 504, a readout circuit 600, and a signal processing circuit 700. The pixel section 504 includes a plurality of pixels 502 that capture an image of a subject.

The plurality of pixels 502 are arranged in a matrix in a first direction D1 (row direction) and a second direction D2 (column direction) intersecting the first direction D1. As will be described in detail later, each of the plurality of pixels 502 includes a plurality of transistors (FIG. 3), a plurality of capacitive elements (FIG. 3), and a light receiving element (FIG. 3) constituting a pixel circuit 60. For example, the light receiving element according to one embodiment of the present invention is a photoelectric conversion element 110 (see FIG. 3) that generates photovoltaic power. More specifically, the photoelectric conversion element 110 is a photodiode.

The power supply circuit 200 is electrically connected to the drive timing control circuit 300, the signal processing circuit 700, the readout circuit 600, and the row selection circuit 400. The power supply circuit 200 includes a logic circuit (not shown) and a voltage generation circuit (not shown). The power supply circuit 200 generates a signal or a power supply voltage using a logic circuit and a voltage generation circuit, and supplies the generated signal, power supply voltage, or power to the drive timing control circuit 300, the signal processing circuit 700, the readout circuit 600, and the row selection circuit 400.

The drive timing control circuit 300 is electrically connected to the signal processing circuit 700, the readout circuit 600, and the row selection circuit 400. For example, the drive timing control circuit 300 generates a timing signal necessary for signal processing of each circuit, and supplies the generated timing signal to each circuit. For example, the timing control signal is a clock signal and a start pulse for controlling the row selection of the row selection circuit 400.

For example, the row selection circuit 400 is arranged at a position adjacent to the pixel section 504 in the first direction D1. For example, a data transfer signal line 412 (see FIG. 3), a reset signal line 414 (see FIG. 3), and a read signal line 410 (see FIG. 3) are connected to the row selection circuit 400. The read signal line 410 is connected to the plurality of pixels 502 arranged in the same row.

The readout circuit 600 is connected to the signal processing circuit 700. For example, the readout circuit 600 is arranged at a position adjacent to the pixel section 504 in the second direction D2. A plurality of output signal lines 420 (see FIG. 3) are connected to the readout circuit 600. The output signal lines 420 are connected to the plurality of pixels 502 arranged in the same column.

For example, the readout circuit 600 includes an AD conversion element (not shown) and a horizontal transfer scanning circuit (not shown). The output signal OUT (n) (see FIG. 3) is supplied to the output signal line 420, and the output signal OUT (n) (see FIG. 3) is converted into a digital signal by the AD conversion element. The digital signal is transferred to the horizontal transfer scanning circuit. The horizontal transfer scanning circuit sequentially reads the digital signals for each column. The horizontal transfer scanning circuit can read the output signal OUT (n) corresponding to each of the plurality of pixels 502 connected to the selected row as the digital signal by using the row selection circuit 400. An output signal OUT (n) is input to the readout circuit 600, and the readout circuit 600 outputs the digital signal.

The signal processing circuit 700 includes an image processing circuit (not shown). For example, an image processing circuit 720 performs image processing such as gamma correction and noise removal on a plurality of digital signals output from the readout circuit 600, and generates image data. For example, the image data is image data of a captured subject. Although not shown, each of the signal processing circuit 700 and the image processing circuit 720 includes an arithmetic processing circuit and a storage circuit. For example, the arithmetic processing circuit in one embodiment of the present invention is a processor, a CPU, or the like, and the storage circuit in one embodiment of the present invention is a volatile memory or a non-volatile memory.

As shown in FIG. 2, the row selection circuit 400 commonly supplies a reset signal RS(n), a read signal RD (n), and a data transfer signal PD (n) to each of the plurality of pixels 502 (the pixel circuit 60) located in an n-th row in the pixel section 504. The power supply circuit 200 supplies a reference voltage VSS, a drive voltage VPP, and a reset voltage VRES to each of the pixel circuits 60 of the plurality of pixels 502 located in an m-th column in the pixel section 504. For example, the plurality of pixels 502 is arranged in a number m along the first direction D1 and in a number n along the second direction D2. The number m and the number n are natural numbers, respectively. For example, the pixels 502 arranged in three rows and five columns are referred to as pixels 502 in three rows and five columns or pixels 502 in coordinates (3, 5).

Each of the plurality of pixels 502 may include a plurality of sub-pixels. For example, one pixel 502 may have three sub-pixels, and each of the three sub-pixels may include the pixel circuit 60. The three sub-pixels may include color filters that exhibit different colors. For example, among the three pixels, the first sub-pixel may include a color filter that exhibits a red color, the second sub-pixel may include a color filter that exhibits a green color, and the third sub-pixel may include a color filter that exhibits a blue color. Also, for example, one pixel 502 may include four or more sub-pixels including color filters that exhibit different colors. For example, the solid-state imaging device 100 includes four or more pixels or sub-pixels including color filters exhibiting different colors, so that it is possible to generate imaging data with high color reproducibility of a subject.

Further, for example, arrangement of the plurality of pixels 502 of the solid-state imaging device 100 is a stripe arrangement. The configuration of the plurality of pixels 502 is not limited, and can be appropriately selected based on application or specification of the solid-state imaging device 100.

Further, signals, power supplies, voltages, and power that are the basis of the respective signals, power supplies, voltages, and power may be supplied from an external circuit (not shown) to the power supply circuit 200, the drive timing control circuit 300, and the signal processing circuit 700. The power supply circuit 200, the drive timing control circuit 300, and the signal processing circuit 700 may generate and supply a desired signal, a desired power supply, a desired voltage, and a desired power according to the row selection circuit 400, the pixel section 504, and the readout circuit 600 based on the supplied signals, power supplies, voltages, and power.

### [1-2. Circuit Configuration of Pixel 502]

The pixel circuit 60 included in the pixel 502 will be described with reference to FIG. 3. FIG. 3 is a circuit diagram showing the pixel circuit 60. Each of the plurality of pixels 502 includes a plurality of transistors constituting the pixel circuit 60, a capacitive element, and a photoelectric conversion element. FIG. 3 shows components constituting the pixel circuit 60 of the pixel 502 of n rows and m columns shown in FIG. 2. The configuration of the pixel circuit 60 shown in FIG. 3 is an example, and the configuration of the pixel circuit 60 is not limited to the configuration shown in FIG. 3. Configurations that are the same as or similar to those in FIG. 1 and FIG. 2 are described as necessary.

As shown in FIG. 3, the pixel circuit 60 includes the data transfer transistor T1 (first transistor), the reset transistor T2 (second transistor), a driving transistor T3 (third transistor), a selection transistor T4 (fourth transistor), the photoelectric conversion element 110, a capacitive element SC1, and the capacitive element SC2. Each transistor includes a gate electrode and a pair of electrodes (a pair of electrodes including a first electrode and a first electrode) including a source electrode and a drain electrode. Each capacitive element includes a pair of electrodes (a first electrode and a second electrode). In addition, functions as the source and functions as the drain of each electrode may be interchanged depending on the voltage applied to the source electrode and the drain electrode.

As a power supply for driving the pixel 502, the drive voltage VPP is supplied to the drive power supply line PVDD, and the reference voltage VSS is supplied to a reference potential line PVSS. The reset voltage VRES is supplied to the reset potential line SVR. The reset voltage VRES is a constant voltage capable of resetting or initializing the pixel 502, and is supplied to the node N2 by controlling the reset transistor T2. The reset voltage VRES may be a constant voltage and may be a variable voltage depending on the duration. For example, the reset voltage VRES of the solid-state imaging device 100 is a constant voltage.

The data transfer transistor T1 has a function of bringing the node N1 into conduction with the node N2 and supplying a voltage based on the photovoltaic power generated by the light received by the photoelectric conversion element 110 along with the exposure of the pixel 502 from the node N1 to the node N2. In other words, the data transfer transistor T1 has a function of transferring the voltage generated by the photoelectric conversion element 110 from the node N1 to the node N2. The data transfer transistor T1 includes a gate electrode 612, a first electrode 614, and a second electrode 616. The gate electrode 612 is electrically connected to the data transfer signal line 412. The first electrode 614 is electrically connected to the node N1, a second electrode 24 of the capacitive element SC1, and the second electrode 14 of the photoelectric conversion element 110. The second electrode 616 is electrically connected to the node N2, a first electrode 624 of the reset transistor T2, a gate electrode 632 of the drive transistor T3, and a second electrode 34 of the capacitive element CS2. The data transfer signal PD (n) is supplied to the data transfer signal line 412. The data transfer transistor T1 is switched using the data transfer signal PD (n). In other words, in the data transfer transistor T1, a conduction state (an on state) and a non-conduction state (an off state) are controlled by the data transfer signal PD (n). In the case where the signal supplied to the data transfer signal PD (n) is at a LO level, the data transfer transistor T1 becomes non-conductive. In the case where the signal supplied to the data transfer signal PD (n) is at an HI level, the data transfer transistor T1 becomes conductive.

The reset transistor T2 has a function of supplying the reset voltage VRES to the node N2 and bringing the pixel 502 into a reset state or an initialization state. The reset transistor T2 includes a gate electrode 622, the first electrode 624, and a second electrode 626. The gate electrode 622 is electrically connected to the reset signal line 414. The second electrode 626 is electrically connected to the reset potential line SVR. The reset signal RS (n) is supplied to the reset signal line 414. The reset transistor T2 is switched using the reset signal RS (n). In other words, the reset transistor T2 is controlled to be in a conductive state (ON state) or a non-conductive state (OFF state) by the reset signal RS (n). In the case where the signal supplied to the reset signal RS (n) is at the LO level, the reset transistor T2 becomes non-conductive. In the case where the signal supplied to the reset signal RS (n) is at the HI level, the reset transistor T2 becomes conductive.

The driving transistor T3 adjusts the voltage supplying the node N3 in the reset state or the initialization state by the reset voltage VREF supplied to the gate electrode 632 to a voltage corresponding to the node N2. Further, the driving transistor T3 adjusts the voltage supplying the node N3 in accordance with the current based on the photovoltaic power generated by the light received by the photoelectric conversion element 110 in accordance with the exposure of the pixel 502 to the voltage corresponding to the node N2. In addition, in one embodiment of the present invention, the exposure of the pixel 502 may be referred to as the pixel 502 receiving light or exposing the pixel 502 to light, and the photoelectric conversion element 110 receiving light may be referred to as the exposure of the photoelectric conversion element 110 and exposing the photoelectric conversion element 110 to light. The driving transistor T3 includes the gate electrode 632, a first electrode 634, and a second electrode 636. The first electrode 634 is electrically connected to the node N3 and a second electrode 646 of the select transistor T4. The second electrode 636 is electrically connected to the drive power supply line PVDD. For example, the threshold voltage of the driving transistor T3 is a threshold voltage VTH. The driving transistor T3 controls a voltage supplied to the node N3 to become a voltage being lower by the threshold voltage VTH than the voltage supplied to the node N2, according to a potential difference Vgs between a voltage supplied to the node N2 and a voltage supplied to the first electrode 634 and a potential difference Vds between a voltage supplied to the second electrode 636 and a voltage supplied to the first electrode 634. For example, if the potential difference Vgs is smaller than the threshold voltage VTH, the second transistor T2 becomes non-conductive. For example, if the potential difference Vgs is equal to or greater than the threshold voltage VTH and the potential difference Vds is larger than 0 V, the driving transistor T3 becomes conductive, and the voltage supplying the node N3 becomes the voltage corresponding to the node N2.

The selection transistor T4 has a function of conducting the node N3 with the output signal line 420 and supplying the voltage supplying the node N3 to the output signal line 420 based on the photovoltaic power generated by the light received by the photoelectric conversion element 110 in accordance with the exposure of the pixel 502. In other words, the selection transistor T4 has a function of supplying the voltage of node N3 to the output signal line 420 based on the voltage generated by the photoelectric conversion element 110. The select transistor T4 includes a gate electrode 642, a first electrode 644, and the second electrode 646. The gate electrode 642 is electrically connected to the read signal line 410. The first electrode 644 is electrically connected to the output signal line 420. The read signal RD (n) is supplied to the read signal line 410. The selection transistor T4 is switched using the read signal RD (n). In other words, in the selection transistor T4, a conductive state (on state) and a non-conductive state (off state) are controlled by the read signal RD (n). If the signal supplied to the read signal RD (n) is at a LO level, the selection transistor T4 becomes non-conductive. If the signal supplied to the read signal RD (n) is HI, the selection transistor T4 becomes conductive.

The capacitive element SC1 has a function of holding charges corresponding to the photovoltaic power generated based on the light received by the photoelectric converting element 110, which is supplied to the node N1. The capacitive element SC1 is provided between the node N1 and the reference potential line PVSS. The capacitive element SC1 includes a first electrode 22 and the second electrode 24. The second electrode 24 is electrically connected to the reference potential line PVSS. A capacitance value of the capacitive element SC1 is a capacitance value Cdiode.

The capacitive element SC2 has a function of holding charges corresponding to the photovoltaic power generated based on the light received by the photoelectric converting element 110 supplied to the node N2. The capacitive element SC2 has a function of holding charges corresponding to the drive voltage VPP supplied to the node N2. The capacitive element SC2 is provided between the node N2 and the drive power supply line PVDD. The capacitive element SC2 includes a first electrode 32 and the second electrode 34. The first electrode 32 is electrically connected to the drive power supply line PVDD, and the second electrode 34 is electrically connected to the node N2. The capacitance value of the capacitive element SC2 is a capacitance value Css. Since the solid-state imaging device 100 has the capacitive element SC2, discharging of charges corresponding to the drive voltage VPP can be suppressed, and the reset state or the initialization state of the pixel 502 can be maintained. In addition, the solid-state imaging device 100 includes the capacitive element SC2, so that discharging of charges corresponding to photovoltaic power can be suppressed and the exposure of the pixel 502 can be maintained. As a result, the solid-state imaging device 100 has excellent long-term reliability because each voltage in the reset state, the initialization state, and the exposure state can be kept constant.

The photoelectric conversion element 110 has a function of generating photovoltaic power by the light received along with the exposure of the pixel 502. Further, the photoelectric conversion element 110 has a function of supplying electric charges corresponding to a current based on the generated photovoltaic power to the node N1 and the capacitive element SC1. The photoelectric conversion element 110 includes a first electrode 12 and the second electrode 14.

The conductive state in the solid-state imaging device 100 indicates a state in which the source electrode and the drain electrode of the transistor are conductive and the transistor is turned into the on (ON) state. The non-conductive state in the solid-state imaging device 100 indicates a state in which the source electrode and the drain electrode of the transistor are non-conductive and the transistor is turned into the off (OFF) state. In addition, in each transistor, the source electrode and the drain electrode may be replaced with each other depending on the voltage of each electrode. In addition, even if the transistor is in the off state, it can be easily understood by a person skilled in the art that a slight current flows, such as a leakage current.

### [1-3. Example of End Face Structure and Layout of Pixel 502]

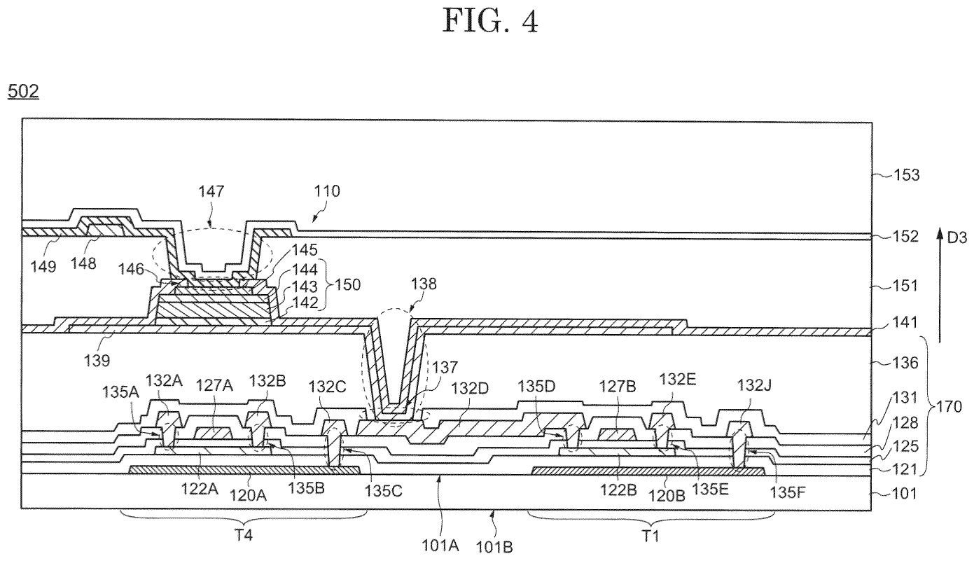

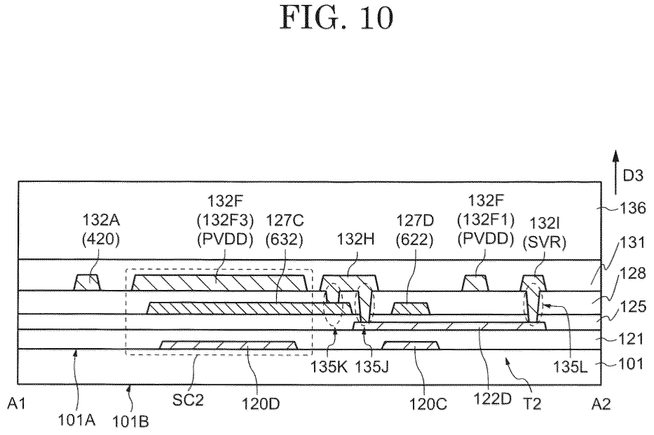

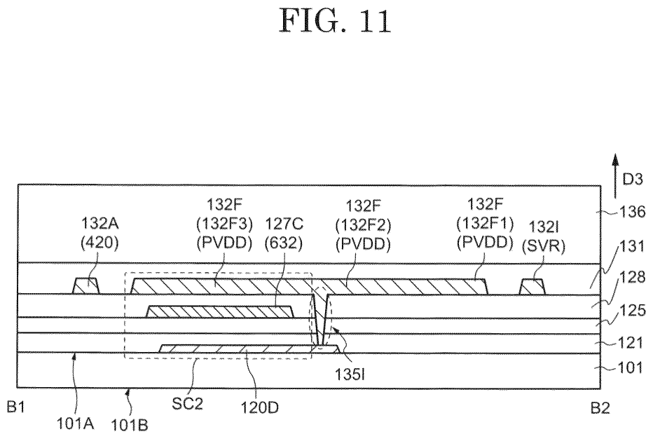

Referring to FIG. 4 to FIG. 11, an example of an end face structure and a layout of the pixel 502 will be described. FIG. 4 is an end view showing an example of an end face structure of the pixel 502. FIG. 5 to FIG. 9 are diagrams showing an example of a layout of the pixels 502. FIG. 10 is an end view showing an end face of the capacitive element CS2 cut along the line A1-A2 of the pixel 502 shown in FIG. 5. FIG. 11 is an end view showing an end face of the capacitive element CS2 cut along the line B1-B2 of the pixel 502 shown in FIG. 5. The configuration of the pixel 502 shown in FIG. 4 to FIG. 11 is an example, and the configuration of the pixel 502 is not limited to the example shown in FIG. 4 to FIG. 11. The same or similar configurations as those in FIG. 1 to FIG. 3 will be described as necessary.

### [1-3-1. End Face Structure of Pixel 502]

First, referring to FIG. 4, an overview of the end face configuration of the pixel 502 will be described with reference to the configuration of the data transfer transistor T1, the configuration of the selection transistor T4, and the configuration of the photoelectric conversion element 110. As shown in FIG. 4, FIG. 10, and FIG. 11, a substrate SUB includes a first surface 101A and a second surface 101B opposed to the first surface 101A along the third direction D3. Each layer included in the solid-state imaging device 100 (pixel 502) is provided above the substrate SUB (a side of the first surface 101A) along the third direction D3.

As shown in FIG. 4, the data transfer transistor T1 includes the oxide semiconductor layer 122B, a gate insulating layer 125, and a gate electrode 127B. The oxide semiconductor layer 122B is electrically connected between the node N1 and the node N2. The gate electrode 127B faces the oxide semiconductor layer 122B. The gate insulating layer 125 is provided between the oxide semiconductor layer 122B and the gate electrode 127B. The oxide semiconductor layer 122B is provided closer to the first surface 101A than the gate electrode 127B, and the data transfer transistor T1 is a so-called top-gate transistor. As an example, although each transistor constituting the solid-state imaging device 100 is a top-gate transistor, each transistor constituting the solid-state imaging device 100 may be a bottom-gate transistor in which the gate electrode 127B is provided closer to the first surface 101A than the oxide semiconductor layer 122B, and the positional relationship between the oxide semiconductor layer 122B and the gate electrode 127B is the opposite to that of a top-gate transistor.

The oxide semiconductor layer 122B in a region overlapping the gate electrode 127B (gate electrode 612) in a plan view functions as the semiconductor layer (channel) of the data transfer transistor T1, and is switched between a conductive state and a non-conductive state in accordance with the voltage supplied to the gate electrode 127B. That is, the oxide semiconductor layer 122B in a region not overlapping the gate electrode 127B in a plan view functions as the conductive layer of the data transfer transistor T1, and is the first electrode 614 and the second electrode 616. That is, the oxide semiconductor layer 122B functions as both the semiconductor layer and the conductive layer.

Along the third direction D3, in ascending order of distance from the first surface 101A, the oxide semiconductor layer 122B is provided on an insulating layer 121, the gate insulating layer 125 is provided on the oxide semiconductor layer 122B, the gate electrode 127B is provided on the gate insulating layer 125, an insulating layer 128 is provided on the gate electrode 127B, conductive layers 132D, 132E, and 132J are provided on the insulating layer 128, and an insulating layer 131 is provided on the conductive layers 132D, 132E, and 132J. The conductive layers 132D and 132E are connected to the oxide semiconductor layer 122B through openings 135D and 135E provided in the insulating layer 128 and the gate insulating layer 125. For example, the voltage generated by the photoelectric conversion element 110 is supplied (transmitted) to the conductive layer 132.

In addition, the data transfer transistor T1 includes a conductive layer 120B. The conductive layer 120B is provided between the oxide semiconductor layer 122B and the substrate SUB. In a plan view, the conductive layer 120B is provided in a region where the gate electrode 127B and the oxide semiconductor layer 122B overlap each other. The conductive layer 132J is connected to the conductive layer 120B via an opening 135F provided in the insulating layer 128, the gate insulating layer 125, and the insulating layer 121. For example, the conductive layer 120B is supplied with a constant voltage through the conductive layer 132J to prevent the light entering from the substrate SUB from reaching the oxide semiconductor layer 122B. Similar to the gate electrode 127B, the conductive layer 120B may be energized to control the current flowing through the oxide semiconductor layer 122B. In this case, the conductive layers 120B may be connected to the gate electrode 127B in peripheral regions of the pixel circuit 60.

Further, as will be described later, along the third direction D3, an insulating layer 136 is provided on the insulating layer 131 in ascending order of distance from the first surface 101A, an insulating layer 141 is provided on the insulating layer 136, an insulating layer 151 is provided on the insulating layer 141, an insulating layer 152 is provided on the insulating layer 151, and an insulating layer 153 is provided on the insulating layer 152.

Further, as will be described later, a conductive layer 139 may be provided between the insulating layer 141 and the insulating layer 136, and the conductive layer 139, an n-type semiconductor layer 142, a semiconductor layer 143, a p-type semiconductor layer 144, and a conductive layer 145 may be stacked in this order from the side closer to the first surface 101A along the third direction D3, and may be provided between the insulating layer 141 and the insulating layer 136. The conductive layer 139 may be provided so as to overlap the data transfer transistor T1, and the conductive layer 139, the n-type semiconductor layer 142, the semiconductor layer 143, the p-type semiconductor layer 144, and the conductive layer 145 may be provided so as to overlap the data transfer transistor T1.

As shown in FIG. 4, the selection transistor T4 has the same configuration as that of the data transfer transistor T1. For example, the selection transistor T4 includes a conductive layer 120A, an oxide semiconductor layer 122A, the gate insulating layer 125, a gate electrode 127A, and conductive layers 132A, 132B, and 132C. The conductive layer 120A is formed in the same layer as the conductive layer 120B, the oxide semiconductor layer 122A is formed in the same layer as the oxide semiconductor layer 122B, the gate electrode 127A is formed in the same layer as the gate electrode 127B, and the conductive layers 132A, 132B, and 132C are formed in the same layer as the conductive layers 132D, 132E and 132F.

In a plan view, the oxide semiconductor layer 122A in a region overlapping the gate electrode 127A (gate electrode 642) functions as a semiconductor layer (a channel) of the data transfer transistor T1, and is switched between a conductive state and a non-conductive state in accordance with the voltage supplied to the gate electrode 127A. That is, in a plan view functions the oxide semiconductor layer 122A in a region not overlapping the gate electrode 127A functions as the conductive layer of the data transfer transistor T1, and is the first electrode 644 and the second electrode 646. That is, the oxide semiconductor layer 122B functions as both the semiconductor layer and the conductive layer. The conductive layer 132C is connected to the conductive layer 120A via an opening 135C provided in the insulating layer 128, the gate insulating layer 125, and the insulating layer 121.

In addition, the reset transistor T2, the drive transistor T3, and the transistors included in the solid-state imaging device 100 are formed in the same manner as the data transfer transistor T1 and the selection transistor T4.

As shown in FIG. 4, the photoelectric conversion element 110 includes the conductive layer 139, the n-type semiconductor layer 142, the semiconductor layer 143, the p-type semiconductor layer 144, and the conductive layer 145.

The conductive layer 139 is provided on the insulating layer 136, the n-type semiconductor layer 142 is provided on the conductive layer 139 so as to be in contact with the conductive layer 139, the semiconductor layer 143 is provided on the n-type semiconductor layer 142 so as to be in contact with the n-type semiconductor layer 142, the p-type semiconductor layer 144 is provided on the semiconductor layer 143 so as to be in contact with the semiconductor layer 143, and the conductive layer 145 is provided on the p-type semiconductor layer 144 so as to be in contact with the p-type semiconductor layer 144.

The conductive layer 139 is connected to the conductive layer 132D through an opening 137 provided in the insulating layer 131 and an opening 138 provided in the insulating layer 136. That is, the conductive layer 139 is in contact with the conductive layer 132D at the bottom of the opening 138, and the conductive layer 139 is electrically connected to the data transfer transistor T1. The conductive layer 139 functions as a lower electrode constituting the photoelectric conversion element 110. Further, for example, a portion of the conductive layer 139 functions as the second electrode 14 of the photoelectric transducer 110, and functions as the second electrode 24 of the capacitive element SC1.

Further, for example, the n-type semiconductor layer 142, the semiconductor layer 143, and the p-type semiconductor layer 144 constitute a light emitting diode 150 and function as a light emitting diode. The conductive layer 145 functions as an upper electrode constituting the photoelectric conversion element 110. Further, for example, a portion of the conductive layer 145 functions as the first electrode 12 of the photoelectric transducer 110, and functions as the first electrode 22 of the capacitive element SC1.

Further, the insulating layer 141 is provided on an upper surface and a side surface of the conductive layer 145, an upper surface and a side surface of the p-type semiconductor layer 144 not in contact with the conductive layer 145, a side surface of the semiconductor layer 143, a side surface of the n-type semiconductor layer 142, an upper surface and a side surface of the conductive layer 139 not in contact with the n-type semiconductor layer 142, and an upper surface of the insulating layer 136 not in contact with the conductive layer 139.

A conductive layer 148 is provided on the insulating layer 151. A conductive layer 149 covers an upper surface and a side surface of the conductive layer 148, and is provided on an upper surface and a side surface of the insulating layer 151 in which the conductive layer 148 opened by an opening 147 is not provided, an upper surface and a side surface of the insulating layer 141 is opened by an opening 146, and the conductive layer 145 is exposed from the insulating layer 141. That is, the conductive layer 149 is electrically connected to the conductive layer 148, and is electrically connected to the conductive layer 145 exposed from the insulating layer 141 via the opening 147 that opens the insulating layer 151 and the opening 146 that opens the insulating layer 141. For example, the conductive layer 149 and the conductive layer 148 function as the reference potential line PVSS.

The insulating layer 152 is provided on an upper surface and a side surface of the conductive layer 149 and the insulating layer 151 on which the conductive layer 149 is not provided, and the insulating layer 153 is provided on the insulating layer 152.

In addition, in the case where the conductive layers 120 are distinguished, the conductive layers 120 are represented by numbers and letters, such as the conductive layer 120A, 120B, or the like. Oxide semiconductor layers 122, gate electrodes 127, conductive layers 132, openings 135, openings 138, conductive layers 139, light emitting diodes 150, conductive layers 145, conductive layers 148, conductive layers 149, openings 146, and the openings 147 are also represented by numbers and letters following numbers in order to distinguish them from each other in the same manner as the conductive layers 120. Further, for example, in the case of distinguishing each layer and each opening, the layer and opening may be represented by numbers and letters following numbers such as conductive layers 132F1, 132F2, or the like.

### [1-3-2. Layout of Pixel 502]

Next, an overview of the layout of the pixels 502 will be described with reference to FIG. 5 to FIG. 9. The same or similar configurations as those in FIG. 1 to FIG. 4 will be described as necessary.

For example, the pixel 502 shown in FIG. 5 includes the conductive layer 120, the oxide semiconductor layer 122, the gate electrode 127B, the conductive layer 132, the opening 135, an opening 138A, and the opening 137. Layers above the conductive layer 139 from the side closer to the first surface 101A along the third direction are omitted in FIG. 5.

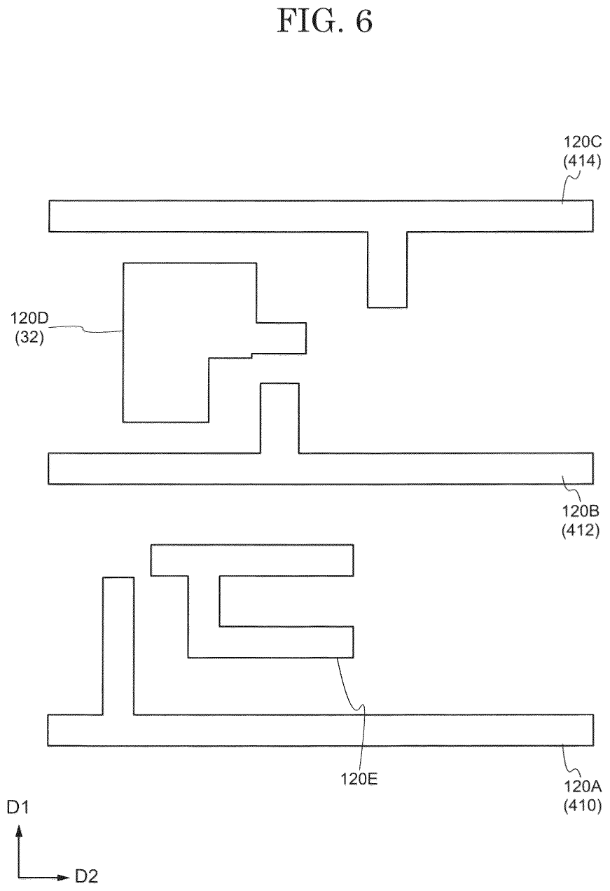

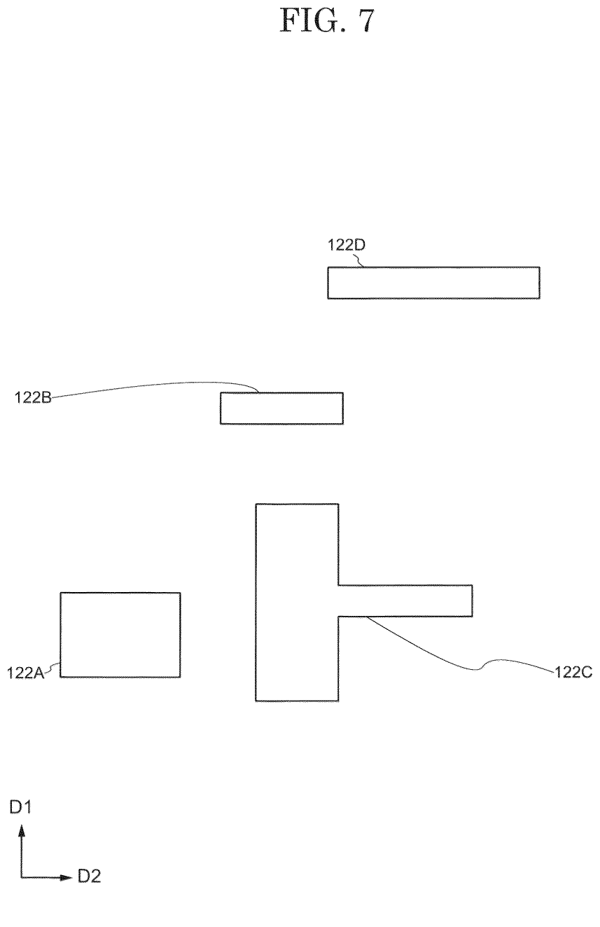

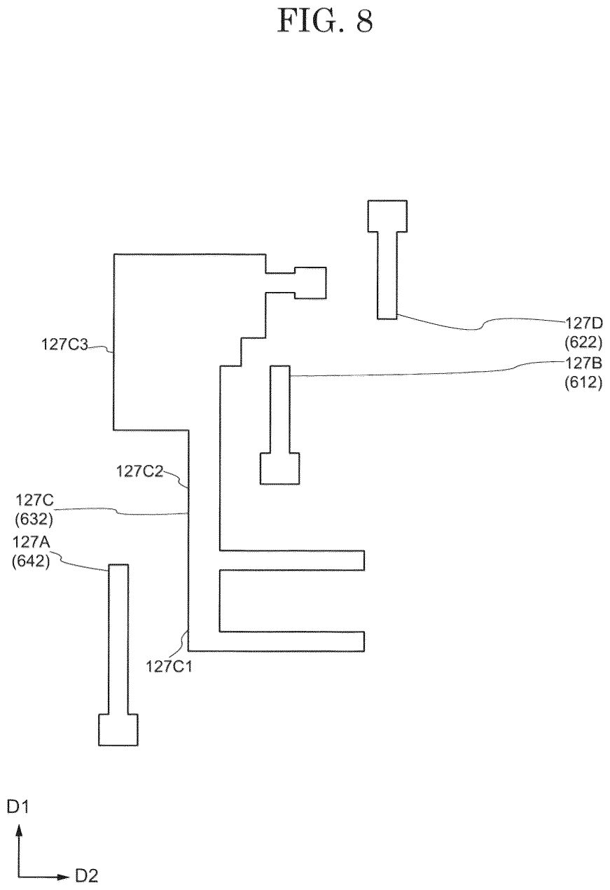

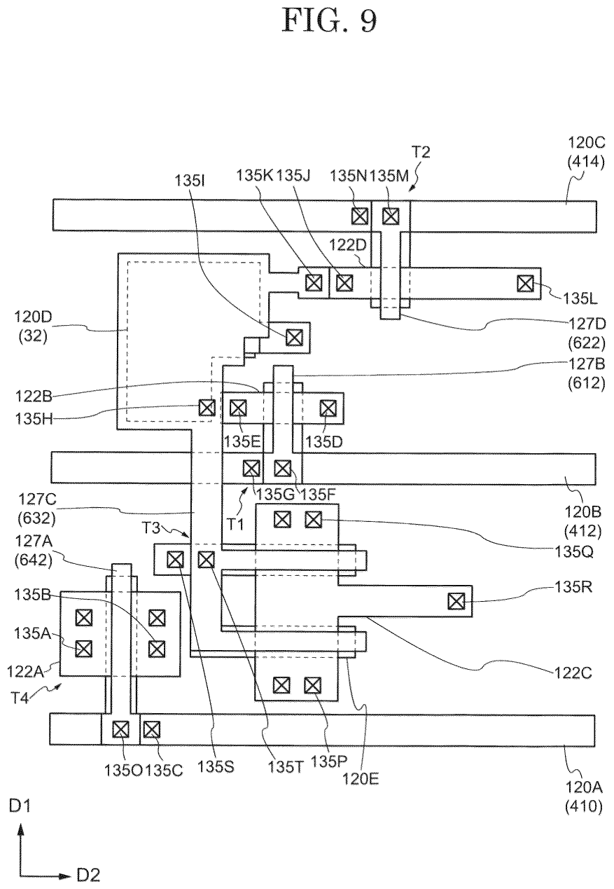

For ease of understanding, FIG. 6 is a diagram showing a layout of the conductive layer 120, FIG. 7 is a diagram showing a layout of the oxide semiconductor layer 122, FIG. 8 is a diagram showing a layout of the gate electrode 127, and FIG. 9 is a diagram showing a layout on which the conductive layer 120, the oxide semiconductor layer 122, the conductive layer 132, the gate electrode 127, and the opening 135 overlapping each other.

As shown in FIG. 5 and FIG. 6, the conductive layers 120 include conductive layers 120A, 120B, 120C, 120D, and 120E. The conductive layers 120A, 120B, 120C, 120D, and 120E are provided in the same layer. The conductive layers 120A, 120B, 120C, 120D, and 120E are spaced apart from each other. The conductive layer 120A functions as the read signal line 410, the conductive layer 120B functions as the data transfer signal line 412, the conductive layer 120C functions as the reset signal line 414, the conductive layer 120D functions as the first electrode 32 of the capacitive element SC2, and the conductive layer 120E functions as a light shielding layer or a gate electrode of the driving transistor T3. In addition, the conductive layers 120A, 120B, and 120C overlap corresponding transistors in the same manner as the conductive layer 120E, and function as light shielding layers or gate electrodes of the corresponding transistors. The conductive layer 120 may be referred to as a lower gate electrode.

As shown in FIG. 5 and FIG. 7, the oxide semiconductor layers 122 include oxide semiconductor layers 122A, 122B, 122C, and 122D. The oxide semiconductor layers 122A, 122B, 122C, and 122D are provided in the same layer. The oxide semiconductor layers 122A, 122B, 122C, and 122D are spaced apart from each other. As shown in FIG. 5 and FIG. 8, the gate electrode 127 includes gate electrodes 127A, 127B, 127C, and 127D. The gate electrodes 127A, 127B, 127C, and 127D are provided in the same layers. The gate electrodes 127A, 127B, 127C and 127D are spaced apart from each other.

The oxide semiconductor layer 122C in a region overlapping the gate electrode 127C (gate electrode 632) in a plan view functions as the semiconductor layer (channels) of the driving transistor T3, and is switched between a conductive state and a non-conductive state in accordance with the voltage supplied to the gate electrode 127C. That is, the oxide semiconductor layer 122C in a region not overlapping the gate electrode 127C in a plan view functions as the conductive layer of the driving transistor T3, and is the first electrode 634 and the second electrode 636. That is, the oxide semiconductor layer 122C functions as both the semiconductor layer and the conductive layer.

As shown in FIGS. 5 and 9, the openings 135 include openings 135A to 135T. The opening 135 may pass through the insulating layer 128, may pass through the insulating layer 128 and the gate insulating layer 125, and may pass through the insulating layer 128, the gate insulating layer 125, and the insulating layer 121. As shown in FIG. 5, the conductive layers 132 include conductive layers 132A to 132J. The conductive layers 132A to 132J are provided in the same layer. The conductive layers 132A to 132J are spaced apart from each other.

For example, the opening 135G exposes the conductive layer 120B (the data transfer signal line 412). The conductive layer 132J electrically connects the conductive layer 120B and the gate electrode 127B (the gate electrode 612) via the opening 135F and 135G. In a plan view, the oxide semiconductor layer 122B is sandwiched between the conductive layer 120B and the gate electrode 127B, and the oxide semiconductor layer 122B, the conductive layer 120B, and the gate electrode 127B face each other and overlap each other, so that a part of the data transfer transistor T1 is formed.

The conductive layer 132G electrically connects the conductive layer 120C (the reset signal line 414) and the gate electrode 127D (the gate electrode 622) via the openings 135N and 135M. In a plan view, the oxide semiconductor layer 122D is sandwiched between the conductive layer 120C and the gate electrode 127D, and the oxide semiconductor layer 122D, the conductive layer 120C, and the gate electrode 127D face each other and overlap each other, so that a part of the reset transistor T2 is formed.

The conductive layer 132I electrically connects the conductive layer 120E and the gate electrode 127C (the gate electrode 632) via the openings 135S and 135T. In a plan view, the oxide semiconductor layer 122C is sandwiched between the conductive layer 120E and the gate electrode 127C, and the oxide semiconductor layer 122C, the conductive layer 120E, and the gate electrode 127C face each other and overlap each other, so that a part of the driving transistor T3 is formed.

The conductive layer 132E electrically connects the oxide semiconductor layer 122B and the gate electrode 127C (the gate electrode 632) via the openings 135H and 135E. The first electrode 624 of the reset transistor T2, the gate electrode 632 of the drive transistor T3, the second electrode 616 of the data transfer transistor T1, and the second electrode 34 of the capacitive element SC2 are electrically connected to each other. The connected region is the node N2.

The conductive layer 132F (the drive power supply line PVDD) is electrically connected to the oxide semiconductor layer 122C via the opening 135R, and is electrically connected to the conductive layer 120D (the first electrode 32) via the opening 135I. That is, the conductive layer 132F (the drive power supply lines PVDD) is electrically connected to the drive transistor T3 and the capacitive element SC2.

The conductive layer 132A (output signal line 420) is electrically connected to the oxide semiconductor layer 122A via the opening 135A. That is, the conductive layer 132A (the output signal lines 420) is electrically connected to the selection transistors T4.

Further, although the detailed explanation is omitted, other insulating layers, conductive layers, gate electrodes, or oxide semiconductor layers corresponding to each of the openings 135 are exposed to conduct the conductive layer and the conductive layer, the conductive layer and the gate electrode, or the conductive layer and the oxide semiconductor layer.

### [1-3-3. Configuration of Capacitive Element CS2 and Reset Transistor T2 of Pixel 502]

Next, configurations of the capacitive element CS2 and the reset transistor T2 will be described referring to FIG. 5 to FIG. 11. The same or similar configurations as those in FIG. 1 to FIG. 4 will be described as necessary.

An end face of the pixel 502 shown in FIG. 10 is an end face along a conductive layer 132A (the output signal line 420), a conductive layer 132F (the drive power supply line PVDD), the gate electrode 127C (the gate electrode 632), the conductive layer 120D, the opening 135K, the conductive layer 132H, the opening 135J, the oxide semiconductor layer 122D, the conductive layer 120C, the gate electrode 127D (the gate electrode 622), the conductive layer 132F (the drive power supply line PVDD), the opening 135L, and the conductive layer 132I (the reset potential line SVR) as an example of the end face of the capacitive element CS2 and the end face of the reset transistor T2. The conductive layer 132A (the output signal line 420), the conductive layer 132F (the drive power supply line PVDD), the conductive layer 120D, the conductive layer 132H, and the conductive layer 132I (the reset potential line SVR) are spaced apart from each other in the same layer.

The end face of the pixel 502 shown in FIG. 11 is an end face of a region obtained by translating the end face shown in FIG. 10 along the first direction D1, and is an end face along the conductive layer 132A (the output signal line 420), the conductive layer 132F (the drive power supply line PVDD), the gate electrode 127C (the gate electrode 632), the conductive layer 120D, the opening 135I, and the conductive layer 132I (the reset potential line SVR).

The gate electrode 127C (the gate electrode 632) includes a gate electrode 127C1 that functions as a gate electrode of the driving transistor T3, a gate electrode 127C3 that overlaps the conductive layer 120D and the conductive layer 132F that comprises the capacitive element CS2 and has an area larger than the conductive layer 120D and an area smaller than the conductive layer 132F, and a gate electrode 127C2 that extends in the first direction D1 and electrically connects the gate electrode 127C1 and the gate electrode 127C3. Further, the conductive layer 132F includes a conductive layer 132F1, a conductive layer 132F3 and a conductive layer 132F2. The conductive layer 132F1 extends in the first direction D1, the conductive layer 132F3 overlaps the conductive layer 120D and the gate electrode 127C comprising the capacitive element CS2 and has an area larger than the conductive layer 120D and the gate electrode 127C, and the conductive layer 132F2 electrically connects the conductive layer 132F1 and the conductive layer 132F3.

As shown in FIG. 5, the capacitive element CS2 has a configuration in which the conductive layer 120D, the gate electrode 127C, and the conductive layer 132F overlap each other in a plan view. As shown in FIG. 10 and FIG. 11, the insulating layer 121 and the gate insulating layer 125 are sandwiched between the conductive layer 120D and the gate electrode 127C, and the insulating layer 128 is sandwiched between the gate electrode 127C and the conductive layer 132F. Further, as shown in FIG. 11, the conductive layer 132F is electrically connected to the conductive layer 120D through the opening 135I that penetrates the insulating layer 121 and the gate insulating layer 125 and exposes the conductive layer 120D. That is, the capacitive element CS2 comprises a capacitance formed by the conductive layer 120D and the gate electrode 127C sandwiching the insulating layer 121 and the gate insulating layer 125 therebetween and a capacitance formed by the gate electrode 127C and the conductive layer 132F sandwiching the insulating layer 128 therebetween. In addition, the capacitive element CS2 may not have the conductive layer 120D, and in this case, the pixel 502 does not have the opening 135I.

As shown in FIG. 5, FIG. 7, or FIG. 10, the reset transistor T2 includes the oxide semiconductor layer 122D, the gate insulating layer 125, and the gate electrode 127D. The oxide semiconductor layer 122D is electrically connected between the node N2 and the reset potential line SVR to which the reset voltage VREF is supplied. The gate electrode 127D faces the oxide semiconductor layer 122D. The gate insulating layer 125 is provided between the oxide semiconductor layer 122D and the gate electrode 127D. The oxide semiconductor layer 122D is provided closer to the first surface 101A than the gate electrode 127D. Further, the oxide semiconductor layer 122D faces the conductive layer 120D arranged on the first surface 101A with the insulating layer 121 sandwiched therebetween.

As shown in FIG. 5 and FIG. 10, the conductive layer 132H electrically connects the gate electrode 127C (the gate electrode 632) and the oxide semiconductor layer 122D via the opening 135K that penetrates the insulating layer 128 to expose the gate electrode 127C (gate electrode 632) and the opening 135J that penetrates the insulating layer 128 and the gate insulating layer 125 to expose the oxide semiconductor layer 122D. The conductive layer 132I (the reset potential line SVR) is electrically connected to the oxide semiconductor layer 122D through the opening 135L that penetrates the insulating layer 128 and the gate insulating layer 125 and exposes the oxide semiconductor layer 122D. For example, the oxide semiconductor layer 122D exposed by the opening 135J is the first electrode 624, and the oxide semiconductor layer 122D exposed by the opening 135L is the second electrode 626. That is, the gate electrode 127C (the gate electrode 632) and the conductive layer 132I (the reset potential line SVR) are electrically connected to the reset transistor T2.

The oxide semiconductor layer 122B in a region overlapping the gate electrode 127D (gate electrode 622) in a plan view functions as the semiconductor layer (channel) of the reset transistor T2, and is switched between a conductive state and a non-conductive state in accordance with the voltage supplied to the gate electrode 127D. That is, the oxide semiconductor layer 122D in the region not overlapping the gate electrode 127D in a plan view functions as the conductive layer of the reset transistor T2, and is the first electrode 624 and the second electrode 626. That is, the oxide semiconductor layer 122D functions as both the semiconductor layer and the conductive layer.

For example, in a pixel of a conventional solid-state imaging device, the conductive layer 132F1 and the gate electrode 127C3 are electrically connected to each other via the conductive layer 132 and the opening 135. The regions formed by the conductive layer 132F1, the gate electrode 127C3, and the conductive layer 132 correspond to the first electrode 614 and the node N2 of the data transfer transistor T1. In addition, the first electrode 614 of the data transfer transistor T1 corresponds to the node N1. Further, the conductive layer 139 (a lower electrode of the photoelectric conversion element 110) is provided upward along the third direction D3, and the conductive layer 139 (the lower electrode of the photoelectric conversion element 110) overlaps the node N2 and the node N1. Parasitic capacitance due to overlap between the node N2 and the lower electrode of the photoelectric conversion element 110 is added to the node N2, and the parasitic capacitance has a large influence on the node N2. In addition, a parasitic capacitance due to coupling with the node N1 is added to the node N2, and the parasitic capacitance has a large influence on the node N2. Consequently, the parasitic capacitance of the node N2 increases, and the noises caused by the increased parasitic capacitance have a large influence on the node N2. Further, the conductive layer 132I (the reset potential line SVR) is electrically connected to the reset transistor T2 via the opening 135, the gate electrode 127, the conductive layer 132, and the plurality of openings 135. Since the plurality of openings 135 are arranged along the second direction D2 between the conductive layer 132I (the reset potential line SVR) and the conductive layer 132 corresponding to the first electrode of the capacitive element SC2, it is difficult to increase the capacitance value of the capacitive element SC2.

On the other hand, in the gate electrode 127C of the pixel of the solid-state imaging device 100, the gate electrodes 127C1, 127C2, and 127C3 are integrated, and in the conductive layer 132F of the pixel of the solid-state imaging device 100, the conductive layer 132F1, the conductive layer 132F2, and the conductive layer 132F3 are integrated. The gate electrode 127C3, which is a part of the node N2, overlaps the conductive layer 132F3. The conductive layer 132F3 is the first electrode 32 of the capacitive element SC2, and the drive voltage VPP which is a constant voltage is supplied to the conductive layer 132F3. Therefore, since the conductive layer 132F3 is arranged between the node N2 and the lower electrode of the photoelectric conversion element 110, the conductive layer 132F3 can cover the gate electrode 127C3 which is a part of the node N2 and shields the lower electrode of the photoelectric conversion element 110 with respect to the gate electrode 127C3. Further, since the gate electrode 127C is not formed in the conductive layer 132, the gate electrode 127C can suppress parasitic capacitance due to coupling with the node N1 formed by the conductive layer 132D. As a consequence, the capacitance value between the conductive layer 132F (the drive power supply line PVDD) and the node N2 can be increased, and the parasitic capacitance between the node N2 and the node N1 can be reduced.

In addition, the conductive layer 132I (the reset potential line SVR) is electrically connected to the oxide semiconductor layer 122D (the second electrode 626 of the reset transistor T2) via the opening 135L. Consequently, it is possible to reduce the number of openings 135 provided between the conductive layer 132I (the reset potential line SVR) and the conductive layer 132F3 constituting the capacitive element SC2. Therefore, an area of the conductive layer 132F3, an area of the conductive layer 120D, and an area of the gate electrode 127C3 constituting the capacitive element SC2 can be increased. As a consequence, the capacitance value between the conductive layers 132F (drive power supply line PVDD) and the node N2 can be increased.

For example, as shown in Table 1, in the conventional solid-state imaging device, a proportion of the capacitance value added to the node N2 is approximately 14% due to the node N1, and approximately 68% due to the drive power supply line PVDD. Further, as shown in Table 1, in the conventional solid-state imaging device, a proportion of the capacitance value added to the node N2 is approximately 5% due to the node N1, and approximately 82% due to the drive power supply line PVDD. Therefore, in the configuration of the capacitive element SC2 of the solid-state imaging device 100, the capacitance value caused by the node N1 is smaller than that of the configuration of the capacitive element SC2 of the conventional solid-state imaging device, and the capacitance value caused by the drive power supply line PVDD is larger than that of the configuration of the capacitive element SC2 of the conventional solid-state imaging device. As a result, the solid-state imaging device 100 has a configuration capable of reducing the parasitic capacitance caused by the coupling, and has a configuration capable of increasing the ratio of the capacitance value to the power supply voltage, so that it is possible to suppress the influence of the coupling and suppress the influence of noise.

TABLE 1

| | | Capacitance value added to |
|---|---|---|
| | Capacitance value added to | node N2 of solid-state |
| | node N2 of conventional | imaging device of the present |
| | solid-state imaging device | invention |
| Node N1 | 14% | 5% |
| Drive power | 68% | 82% |
| supply line | | |
| PVDD | | |

### [1-3-4. Material of Each Member of Solid-state Imaging Device 100]

As the substrate SUB, a rigid substrate having a light transmitting property and no flexibility, such as a glass substrate, a quartz substrate, or a sapphire substrate, can be used. Further, in the case where the substrate SUB needs to have flexibility, a flexible substrate including a resin such as a polyimide substrate, an acryl substrate, a siloxane substrate, or a fluorine resin substrate can be used as the substrate SUB. In order to improve the heat resistance of the substrate SUB, the resin may be doped with impurities.

A metal material can be used as the conductive layer 120, the gate electrode 127, the conductive layer 132, the conductive layer 139, and the conductive layer 148. For example, aluminum (Al), titanium (Ti), chromium (Cr), cobalt (Co), nickel (Ni), molybdenum (Mo), hafnium (Hf), tantalum (Ta), tungsten (W), bismuth (Bi), or silver (Ag), or an alloy or compound thereof is used as the metallic material. As a member such as the electrode described above, the metal material described above may be used as a single layer or may be used as a laminate.

A general insulating material can be used as the insulating layer 121, the gate insulating layer 125, the insulating layers 128, 131, and 141, and the insulating layers 136, 151, and 153. For example, as the insulating layer 121, the gate insulating layer 125, the insulating layers 128, 131, and 141, an inorganic insulating layer such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) can be used. As these insulating layers, an insulating layer with few defects can be used. As the insulating layers 136, 151, and 153, an organic insulating material such as a polyimide resin, an acrylic resin, an epoxy resin, a silicone resin, a fluorine resin, or a siloxane resin can be used. In addition, the organic insulating material described above may be used as the insulating layer 121, the gate insulating layer 125, and the insulating layers 128, 131, and 141. As a member such as the insulating layer, the insulating material described above may be used as a single layer or may be used as a laminate.

SiOₓN_{y} and AlOₓN_{y} are silicon compounds and aluminum compounds that contain a smaller proportion (x>y) of nitrogen (N) than oxygen (O). SiNₓO_{y} and AlNₓO_{y} are silicon-containing and aluminum-containing compounds that contain a smaller proportion (x>y) of oxygen than nitrogen.

As the oxide semiconductor layer 122, an oxide semiconductor having characteristics of a semiconductor can be used. The oxide semiconductor layer 122 has a light transmitting property. For example, oxide semiconductors including indium (In), gallium (Ga), zinc (Zn), and oxygen (O) can be used.

For example, a leakage current of a transistor including an oxide semiconductor having characteristics of a semiconductor is extremely small. Therefore, the charge corresponding to the voltage transferred to the capacitive element is less likely to escape from the capacitive element by using the transistor having the oxide semiconductor having the characteristics of the semiconductor. As a result, by using the transistor including the oxide semiconductor having the characteristics of the semiconductor, it is possible to suppress a change in the voltage transferred to the capacitive element. For example, using the data transfer transistor T1, the charge corresponding to the voltage transferred to the capacitive element SC2 is less likely to escape from the capacitive element SC2, and the change in the potential of the voltage transferred to the capacitive element SC2 (the gate electrode 632 and the node N2) is suppressed. In addition, since the change in the voltage of the gate electrode 632 of the drive transistor T3 is suppressed, the voltage supplied to the node N3 is stabilized in accordance with the voltage input to the gate electrode 632. Consequently, since the voltage supplied to the output signal line 420 is stabilized, the output signal OUT (m) includes data with high reproducibility of the subject, and the solid-state imaging device 100 can provide the user with images with high reproducibility of the subject.

A transparent conductive layer is used as the conductive layer 145 and the conductive layer 149. For example, a mixture of indium oxide and tin oxide (ITO) or a mixture of indium oxide and zinc oxide (IZO) can be used as the transparent conductive layers. In addition, a material other than the above may be used as the transparent conductive layer.

The conductive layer 120, the insulating layer 121, the oxide semiconductor layer 122, the gate insulating layer 125, the gate electrode 127B, the insulating layer 128, the holes 135, the conductive layer 132, the insulating layer 131, the insulating layer 136, and the conductive layer 139 may be collectively referred to as an arrayed section 170.

### 2. Second Embodiment

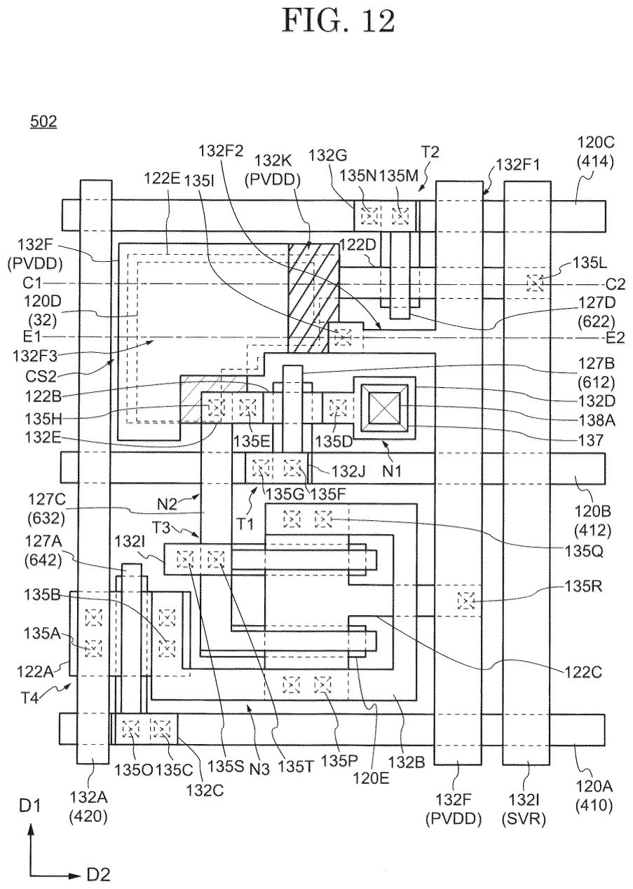

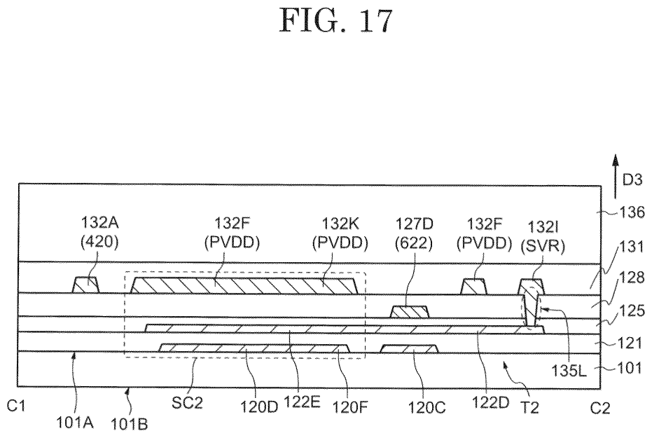

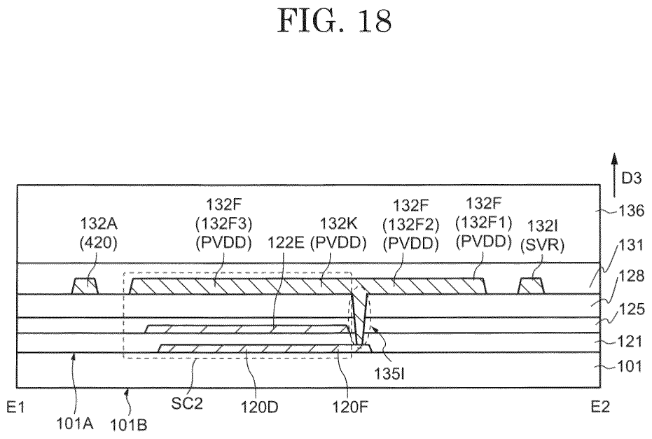

With reference to FIG. 12 to FIG. 18, an overview of a solid-state imaging device according to a second embodiment will be described. FIG. 12 to FIG. 16 are diagrams showing an example of a layout of the pixels 502 of the solid-state imaging device according to the second embodiment. FIG. 17 is an end view showing an end face of the capacitive element CS2 cut along the line C1-C2 of the pixel 502 shown in FIG. 12. FIG. 18 is an end view showing an end face of the capacitive element CS2 cut along the line E1-E2 of the pixel 502 shown in FIG. 12. The configuration of the pixel 502 of the solid-state imaging device according to the second embodiment shown in FIG. 12 to FIG. 18 is an example, and is not limited to the example shown in FIG. 12 to FIG. 18. Configurations that are the same as or similar to those in FIG. 1 to FIG. 18 are described as necessary.

The pixel 502 of the solid-state imaging device according to the second embodiment includes the following configurations (1) to (5). Mainly, the configurations shown in (1) to (5) are different from the configuration of the pixel 502 of the solid-state imaging device 100 according to the first embodiment.

(1) An area of the first electrode 32 of the capacitive element SC2 is increased because the first electrode 32 of the capacitive element SC2 becomes the conductive layer 120D+a conductive layer 120F from the conductive layer 120D.
(2) Since an oxide semiconductor layer 122E is connected to the oxide semiconductor layers 122D and 122B and the oxide semiconductor layers are integrated, the pixel 502 of the solid-state imaging device according to the second embodiment does not include the openings 135K and 135J.
(3) A part corresponding to the gate electrode 127C3 is replaced with the oxide semiconductor layer 122E. That is, the pixel 502 of the solid-state imaging device according to the second embodiment does not include the gate electrode 127C3. The oxide semiconductor layer 122E is connected to the oxide semiconductor layers 122D and 122B, and the oxide semiconductor layers are integrated. For example, the oxide semiconductor layer 122E functions as a part of the second electrode 34 of the capacitive element SC2.
(4) An area of the second electrode 34 of the capacitive element SC2 is increased because a part of the second electrode 34 of the capacitive element SC2 becomes the conductive layer 132F+a conductive layer 132K from the conductive layer 132F.
(5) Due to the increase in the area of the first electrode 32 of the capacitive element SC2 and the increase in the area of the second electrode 34 of the capacitive element SC2, a position where the opening 135I is disposed is shifted toward the conductive layer 132F1.

Configurations other than the configuration shown in (1) to (5) in the pixel 502 of the solid-state imaging device according to the second embodiment and the configuration related to the configuration shown in (1) to (5) in the pixel 502 of the solid-state imaging device according to the second embodiment are the same configuration as the pixel 502 of the solid-state imaging device 100 according to the first embodiment. Therefore, a difference from the pixel 502 of the solid-state imaging device 100 according to the first embodiment will be mainly described here. In describing the configuration and function of the pixel 502 of the solid-state imaging device according to the second embodiment, the same configuration and function as those of the pixel 502 of the solid-state imaging device 100 according to the first embodiment will be described as necessary. Configurations that are the same as or similar to those in FIG. 1 to FIG. 18 will be described as necessary.

### [2-1. Layout of Pixel 502]

Next, an overview of the layout of the pixel 502 of the solid-state imaging device according to the second embodiment will be described with reference to FIG. 12 to FIG. 16. The same or similar configurations as those in FIG. 1 to FIG. 11 will be described as necessary.

For example, in the layout of the pixel 502 shown in FIG. 12, Similar to the layout of the pixel 502 shown in FIG. 5, the conductive layer 120, the oxide semiconductor layer 122, the gate electrode 127B, the conductive layer 132, the opening 135, the opening 138A, and the opening 137 are shown, and the layers above the conductive layer 139 from the side closer to the first surface 101A along the third direction are omitted.

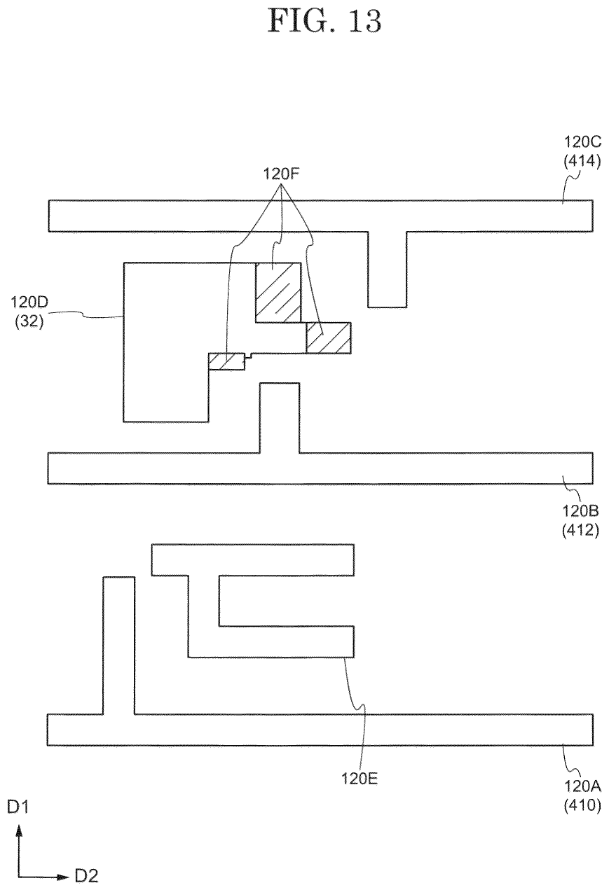

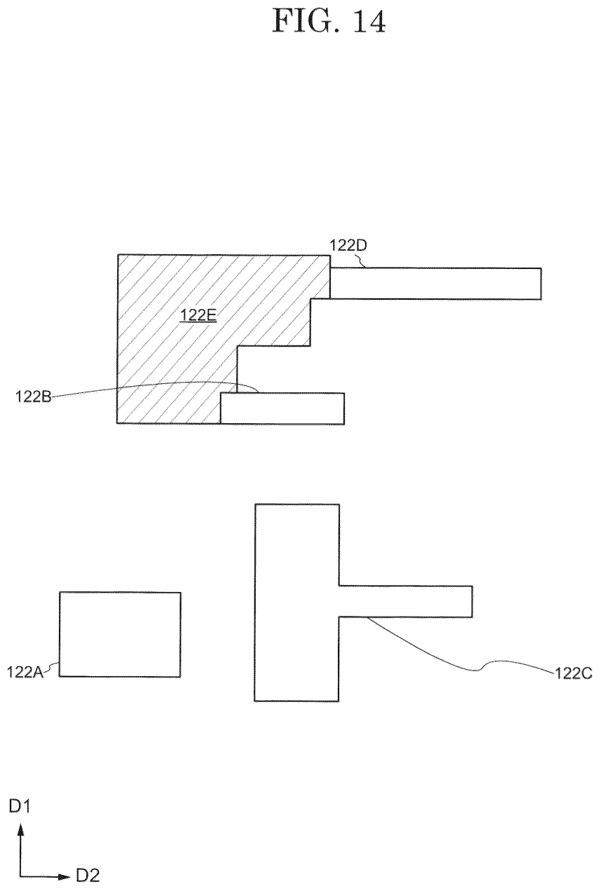

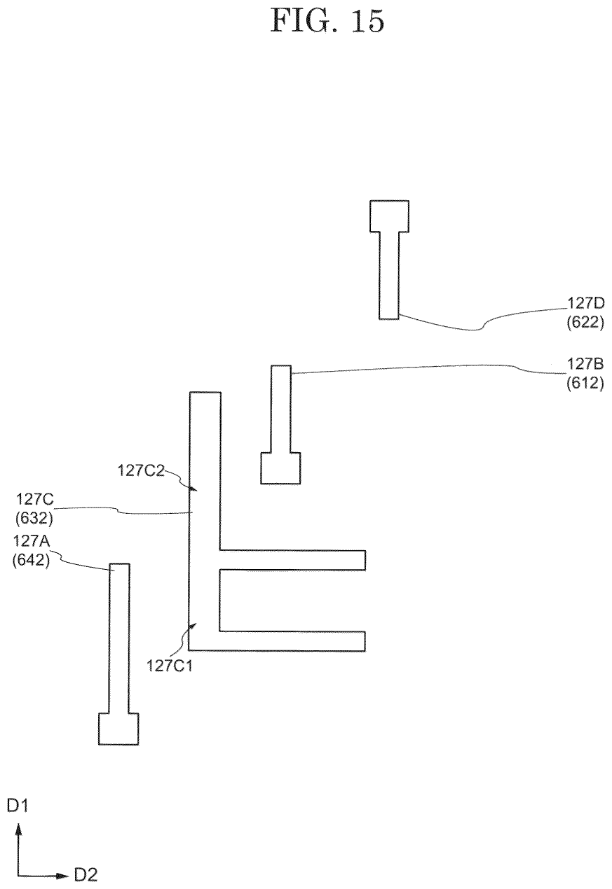

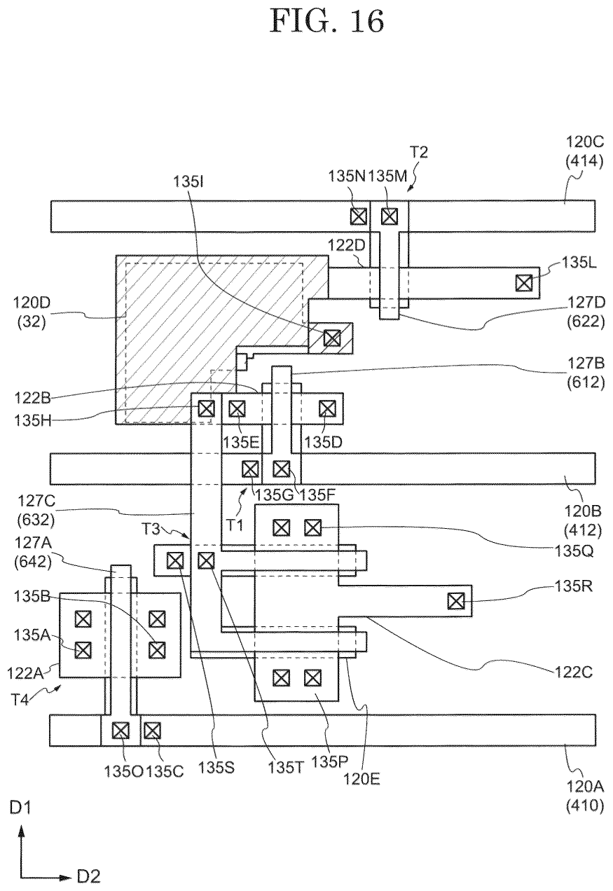

For ease of understanding, FIG. 13 is a diagram showing the layout of the conductive layer 120, FIG. 14 is a diagram showing the layout of the oxide semiconductor layer 122, FIG. 15 is a diagram showing the layout of the gate electrode 127, and FIG. 16 is a diagram showing the layout of the conductive layer 120, the oxide semiconductor layer 122, the conductive layer 132, the gate electrode 127, and the opening 135.

As shown in FIG. 12 and FIG. 13, the conductive layer 120 includes the conductive layers 120A, 120B, 120C, 120D, 120E, and, 120F. The conductive layers 120A, 120B, 120C, 120D, 120E, and 120F are provided in the same layer. The conductive layers 120A, 120B, 120C, and 120D are spaced apart from each other. The conductive layers 120D and 120F function as the first electrodes 32 of the capacitive element SC2.

As shown in FIG. 12 and FIG. 14, the oxide semiconductor layer 122 includes the oxide semiconductor layers 122A, 122B, 122C, 122D, and 122E. The oxide semiconductor layers 122A, 122B, 122C, 122D, and 122E are provided in the same layer. The oxide semiconductor layers 122A, 122B, 122C, and 122D are spaced apart from each other.

In addition, as shown in FIG. 12 and FIG. 15, the gate electrode 127 includes the gate electrodes 127A, 127B, 127C, and 127D. The gate electrodes 127A, 127B, 127C, and 127D are provided in the same layers. The gate electrodes 127A, 127B, 127C, and 127D are spaced apart from each other.

As shown in FIG. 12 and FIG. 16, the opening 135 includes the openings 135A to 1351 and 135L to 135T. The opening 135 may pass through the insulating layer 128, may pass through the insulating layer 128 and the gate insulating layer 125, and may pass through the insulating layer 128, the gate insulating layer 125, and the insulating layer 121. As shown in FIG. 12, the conductive layer 132 includes the conductive layers 132A to 132K. The conductive layers 132A to 132K are provided in the same layer. The conductive layers 132A to 132K are spaced apart from each other.

### [2-2. Configuration of Capacitive Element CS2 and Reset Transistor T2 of Pixel 502]

Next, referring to FIG. 12 to FIG. 18, the configuration of the capacitive element CS2 and the reset transistor T2 will be described. The same or similar configurations as those in FIG. 1 to FIG. 11 will be described as necessary.

The end face of the pixel 502 shown in FIG. 17 is an end face along the conductive layer CS2 (the output signal line 420), the conductive layer 132F (the drive power supply line PVDD), the oxide semiconductor layer 122E, the conductive layer 120D, the gate electrode 127D (the gate electrode 622), the conductive layer 132F (the drive power supply line PVDD), the opening 132A, and the conductive layer 132I (reset potential line SVR) as one of the end faces of the capacitive element CS2 and the reset transistor T2.

The end face of the pixel 502 shown in FIG. 18 is an end face of a region in which the end face shown in FIG. 17 is translated along the first direction D1, and is an end face along the conductive layer 132A (the output signal line 420), the conductive layer 132F (the drive power supply line PVDD), the conductive layer 132K (the drive power supply line PVDD), the oxide semiconductor layer 122E, the conductive layer 120D, the opening 135I, and the conductive layer 132I (the reset potential line SVR).

The gate electrode 127C (the gate electrode 632) includes the gate electrode 127C1 functioning as a gate electrode of the driving transistor T3, and t gate electrode 127C2 extending in the first direction D1 and electrically connected to the gate electrode 127C1. Further, the conductive layer 132F includes the conductive layer 132F1 that electrically connects the conductive layer 132F1 that extend in the direction D1, the conductive layer 132F3+132K that overlaps the conductive layer 120D+120F and the oxide semiconductor layer 122E constituting the capacitive element CS2, and has an area lager than the conductive layer 120D+120F and the oxide semiconductor layer 122E, and the conductive layer 132F2 that electrically connects the conductive layer 132F1 and the conductive layer 132F3+132K.

As shown in FIG. 12, the capacitive element CS2 has a configuration in which the conductive layer 120D+120F, the oxide semiconductor layer 122E, and the conductive layer 132F3+132K overlap each other in a plan view. As shown in FIG. 17 and FIG. 18, the insulating layer 121 is sandwiched between the conductive layer 120D+120F and the oxide semiconductor layer 122E, and the insulating layer 128 and the gate insulating layer 125 are sandwiched between the oxide semiconductor layer 122E and the conductive layer 132F3+132K. As shown in FIG. 18, the conductive layer 132F+132K is electrically connected to the conductive layer 120D+120F through an opening 135I that penetrates the insulating layer 121, the gate insulating layer 125, and the insulating layer 128 to expose the conductive layer 120D. That is, the capacitive element CS2 includes a capacitive element formed by the conductive layer 120D+120F and the oxide semiconductor layer 122E sandwiching the insulating layer 121 therebetween and a capacitive element formed by the oxide semiconductor layer 122E and the conductive layer 132F3+132K sandwiching the insulating layer 128 and the gate insulating layer 125 therebetween.

As shown in FIG. 12, FIG. 14, or FIG. 17, the reset transistor T2 includes the oxide semiconductor layer 122D, the gate insulating layer 125, and the gate electrode 127D. The gate electrode 127D faces the oxide semiconductor layer 122D. The gate insulating layer 125 is provided between the oxide semiconductor layer 122D and the gate electrode 127D. The oxide semiconductor layer 122D is provided on the first surface 101A of the gate electrode 127D. The oxide semiconductor layer 122D faces the conductive layer 120D arranged on the first surface 101A with the insulating layer 121 sandwiched therebetween.

The oxide semiconductor layer 122B in a region overlapping the gate electrode 127D (the gate electrode 622) in a plan view functions as the semiconductor layer (a channel) of the reset transistor T2, and is switched between a conductive state and a non-conductive state in accordance with the voltage supplied to the gate electrode 127D. That is, the oxide semiconductor layer 122D in a region not overlapping the gate electrode 127D in a plan view functions as the conductive layer of the reset transistor T2, and is the first electrode 624 and the second electrode 626. In addition, the oxide semiconductor layer 122E in the region not overlapping the gate electrodes 127D in a plan view functions as the second electrode 34 of the capacitive element SC2. The oxide semiconductor layer 122D is electrically connected to the oxide semiconductor layer 122E. That is, the oxide semiconductor layer 122D+122E functions as both the semiconductor layer and the conductive layer of the reset transistor T2, and also functions as the second electrode 34 of the capacitive element SC2.

The oxide semiconductor layers 122D, 122E, and 122B in the pixel 502 of the solid-state imaging device according to the second embodiment are integrated, and in the conductive layer 132F+132K in the pixel 502 of the solid-state imaging device according to the second embodiment, the conductive layer 132F1, the conductive layer 132F2, the conductive layer 132F3, and 132K are integrated. In addition, the oxide semiconductor layer 122E, which is a part of the node N2, overlaps the conductive layer 132F3. The conductive layer 132F3 is the first electrode 32 of the capacitive element SC2, and the drive voltage VPP which is a constant voltage is supplied to the conductive layer 132F3. Therefore, the conductive layer 132F3 is arranged between the node N2 (the oxide semiconductor layer 122E) and the lower electrode of the photoelectric conversion element 110, so that the conductive layer 132F3 can cover the oxide semiconductor layer 122E which is a part of the node N2 and shield the lower electrode of the photoelectric conversion element 110 with respect to the oxide semiconductor layer 122E. Further, since the oxide semiconductor layer 122E is not formed near the conductive layer 132D, the oxide semiconductor layer 122E can suppress parasitic capacitance due to coupling between the oxide semiconductor layer 122E and the node N1 formed by the conductive layer 132D. As a consequence, the capacitance between the conductive layer 132F (the drive power supply line PVDD) and the node N2 can be increased, and the parasitic capacitance between the node N2 and the node N1 can be reduced.

Further, by integrating the oxide semiconductor layers 122D, 122E, and 122B, it is possible to reduce the opening 135 between the conductive layer 132 and the oxide semiconductor layer 122, and the numbers of the conductive layers 132, the oxide semiconductor layers 122, and the openings 135. Therefore, an area of the conductive layer 132F3, an area of the conductive layer 120D, and an area of the oxide semiconductive layer 122 constituting the capacitive element SC2 can be increased. As a consequence, the capacitance between the conductive layers 132F (the drive power supply line PVDD) and the node N2 can be increased.

As a result, Similar to the solid-state imaging device 100 according to the first embodiment, since the solid-state imaging device according to the second embodiment has a configuration capable of reducing the parasitic capacitance due to coupling, and has a configuration capable of increasing the ratio of the capacitance value of the power supply voltage, it is possible to suppress the influence of the coupling and to suppress the influence of noise. Therefore, Similar to the solid-state imaging device 100 according to the first embodiment, the solid-state imaging device according to the second embodiment has a long-term highly reliable configuration.

### 3. Third Embodiment

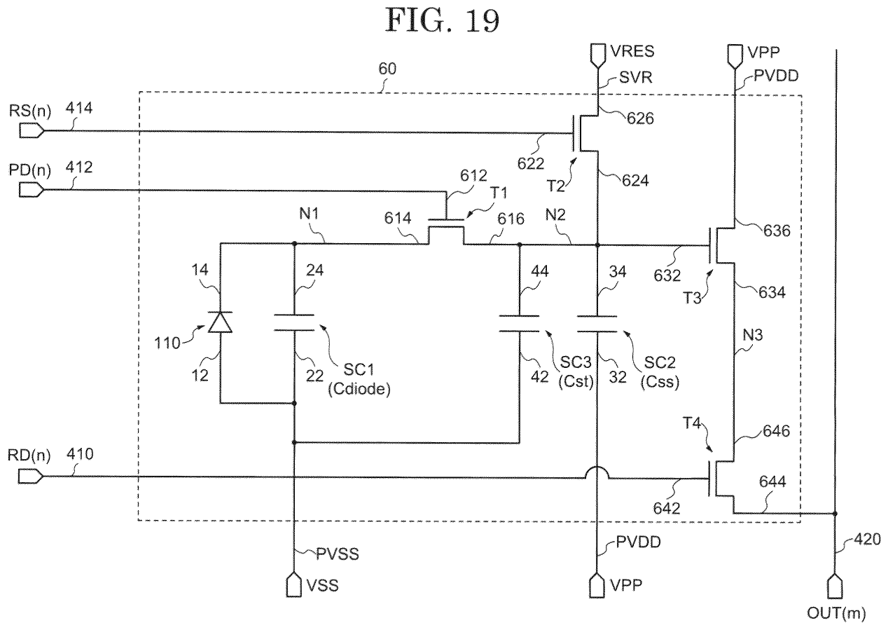

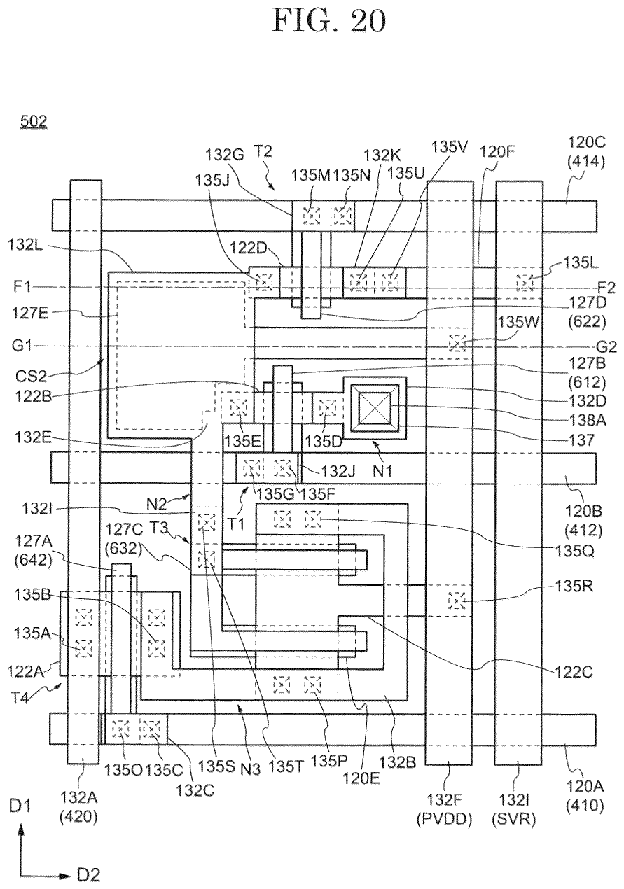

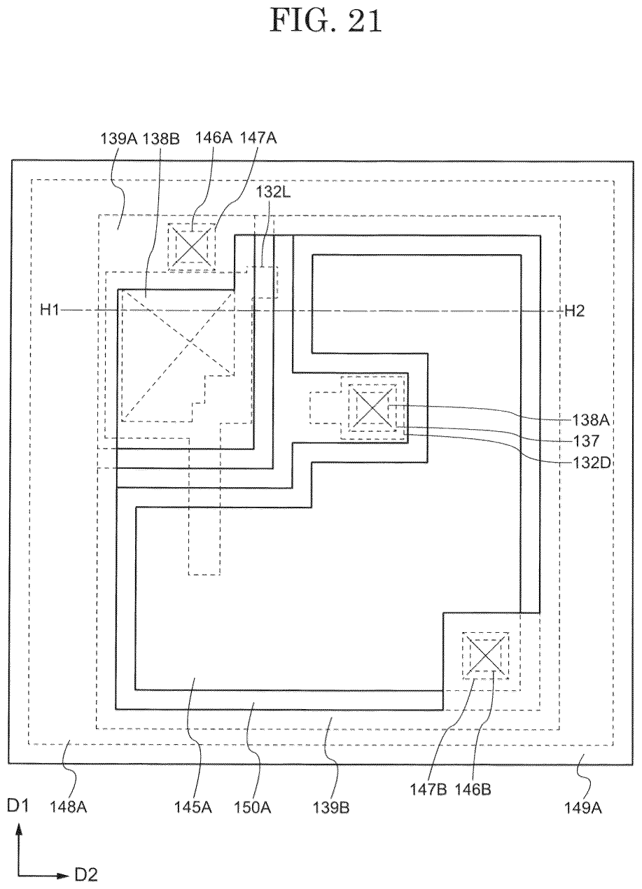

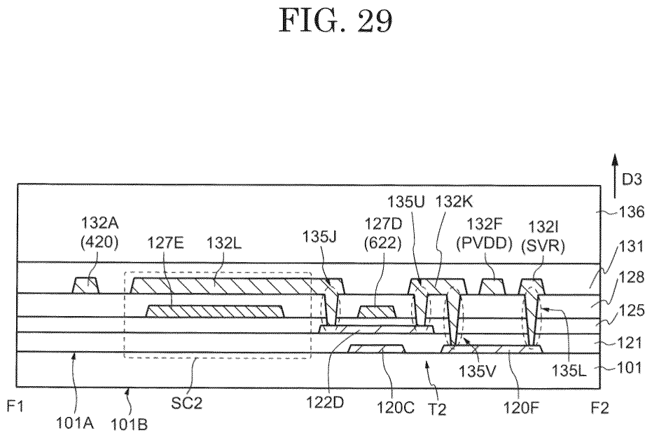

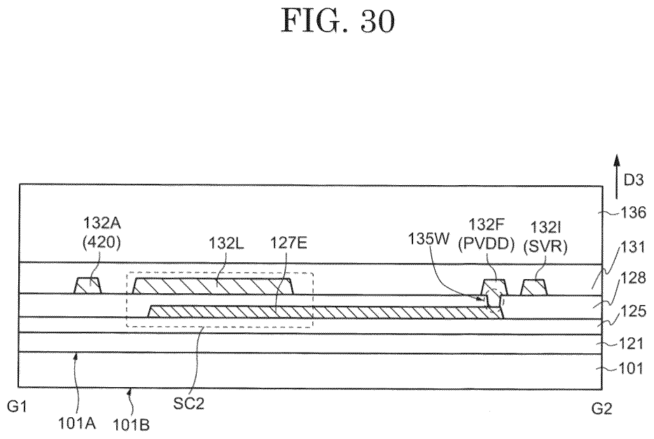

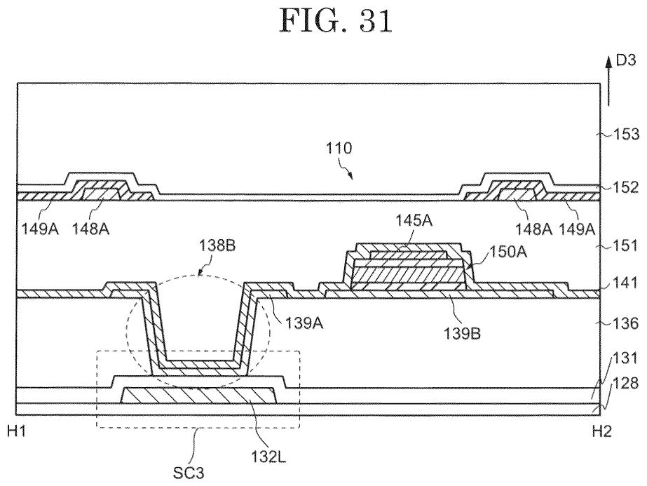

With reference to FIG. 19 to FIG. 31, an overview of a solid-state imaging device according to a third embodiment will be described. FIG. 19 is a circuit diagram showing a pixel circuit of the pixel 502 of the solid-state imaging device according to the third embodiment. FIG. 20 to FIG. 28 are diagrams showing an example of a layout of the pixel 502 of the solid-state imaging device according to the third embodiment. FIG. 29 is an end view showing an end face of the capacitive element CS2 cut along the line F1-F2 of the pixel 502 shown in FIG. 20. FIG. 30 is an end view showing an end face of the capacitive element CS2 cut along the line G1-G2 of the pixel 502 shown in FIG. 20. FIG. 31 is an end view showing an end face of the capacitive element CS3 cut along the line H1-H2 of the pixel 502 shown in FIG. 21. Configurations of the pixel 502 of the solid-state imaging device according to the third embodiment shown in FIG. 19 to FIG. 31 is an example, and is not limited to the example shown in FIG. 19 to FIG. 31. Configurations that are the same as or similar to those in FIG. 1 to FIG. 18 are described as necessary.

The pixel 502 of the solid-state imaging device according to the third embodiment includes the following configurations (6) to (15). Mainly, the configuration shown in (6) to (15) is different from the configuration of the pixel 502 of the solid-state imaging device 100 according to the first embodiment.

(6) A capacitive element SC3 electrically connected between the node N2 and the reference potential line PVSS is included. The capacitive element SC3 includes a first electrode 42 and a second electrode 44. The first electrode 42 is electrically connected to the reference potential line PVSS, and the second electrode 44 is electrically connected to the node N2.
(7) An opening 138B, conductive layers 139A and 139B, a light emitting diode 150A, a conductive layer 145A, a conductive layer 148A, a conductive layer 149A, openings 147A and 147B, and openings 146A and 146B are included.
(8) The solid-state imaging device 100 according to the first embodiment includes a conductive layer 132L in which the conductive layer 132F3 is reduced and the conductive layers 132I, 132F3, 132E, and 132H are integrated.
(9) A position at which the reset transistor T2 is arranged is changed along the second direction D2 so as to be spaced apart from the conductive layer 132F, and the opening 135N and the opening 135M are changed to the opening 135N and the opening 135M in the order of being closer to the conductive layer 132F.
(10) The conductive layer 132I is electrically connected to the conductive layer 120F via the opening 135L, and the conductive layer 120F is electrically connected to the oxide semiconductor layer 122D via an opening 135V, the conductive layer 132K, and an opening 135U. The oxide semiconductor layer 122D is supplied with the reset voltage VRES through the conductive layer 132I, the opening 135L, the conductive layer 120F, the opening 135V, the conductive layer 132K, and the opening 135U.
(11) The gate electrode 127C3 and the gate electrode 127C2 and the opening 135K are not included, and the oxide semiconductor layer 122D is electrically connected to the conductive layer 132L via the opening 135J.
(12) The opening 135H is not included, and the oxide semiconductor layer 122B is electrically connected to the conductive layer 132K via the opening 135E.
(13) The capacitive element SC2 includes the conductive layer 132L, a gate electrode 127E, and the insulating layer 128 between the conductive layer 132L and the gate electrode 127E. The conductive layer 132L is the second electrode 34, and the gate electrode 127E is the first electrode 32.
(14) The gate electrode 127E is electrically connected to the conductive layer 132F (the drive power supply line PVDD) through an opening 135W, and the gate electrode 127E is supplied with the drive voltage VPP.
(15) The conductive layer 148A and the conductive layer 149A are electrically connected to the conductive layer 139A via the opening 147A and the opening 146A. The conductive layer 132L corresponds to the second electrode 44, and the conductive layer 148A, the conductive layer 149A, and the conductive layer 139A correspond to the first electrode 42.

Configurations other than the configuration shown in (6) to (15) in the pixel 502 of the solid-state imaging device according to the third embodiment and the configuration related to the configuration shown in (6) to (15) in the pixel 502 of the solid-state imaging device according to the third embodiment are the same configuration as the pixel 502 of the solid-state imaging device 100 according to the first embodiment. Therefore, a difference from the pixel 502 of the solid-state imaging device 100 according to the first embodiment will be mainly described here. In describing the configuration and function of the pixel 502 of the solid-state imaging device according to the third embodiment, the same configuration and function as those of the pixel 502 of the solid-state imaging device 100 according to the first embodiment will be described as necessary. Configurations that are the same as or similar to those in FIG. 1 to FIG. 27 will be described as necessary.

### [3-1. Circuit Configuration of Pixel 502]

A pixel circuit included in the pixel 502 of the solid-state imaging device of the third embodiment will be described with reference to FIG. 19.

As described in (6) above, the pixel 502 of the solid-state imaging device of the third embodiment includes the capacitive element SC3. In addition, the capacitance value of the capacitive element SC1 is represented by Cdiode, the capacitance value of the capacitive element SC2 is represented by Css, and a capacitance value of the capacitive element SC3 is represented by Cst.

### [3-2. Layout of Pixel 502]

Next, an overview of the layout of the pixel 502 of the solid-state imaging device according to the third embodiment will be described with reference to FIG. 19 to FIG. 25. Configurations that are the same as or similar to those in FIG. 1 to FIG. 18 are described as necessary.

In the layout of the pixel 502 shown in FIG. 20, Similar to the layout of the pixel 502 shown in FIG. 5, the conductive layer 120, the oxide semiconductor layer 122, the gate electrode 127B, the conductive layer 132, the opening 135, the opening 138A, and the opening 137 are shown, and the layer above the conductive layer 139 is omitted from the side closer to the first surface 101A along the third direction.

In the layout of the pixel 502 shown in FIG. 21, the openings 138A, 137 and 138B, the conductive layers 139A and 139B, the light emitting diode 150A, the conductive layer 145A, the conductive layer 148A, the conductive layer 149A, the openings 147A and 146B, and the opening 146A and 146B described in (7) above are shown, and a layer below the conductive layer 139 is omitted from the side closer to the first surface 101A along the third direction D3. In addition, the conductive layer 132L and the conductive layer 132D are shown in FIG. 21, which are layers below the conductive layer 139A along the third direction D3, in order to clearly show that the conductive layer 139A overlaps the conductive layer 132L, and the conductive layer 139B overlaps and is electrically connected to the conductive layer 132D.

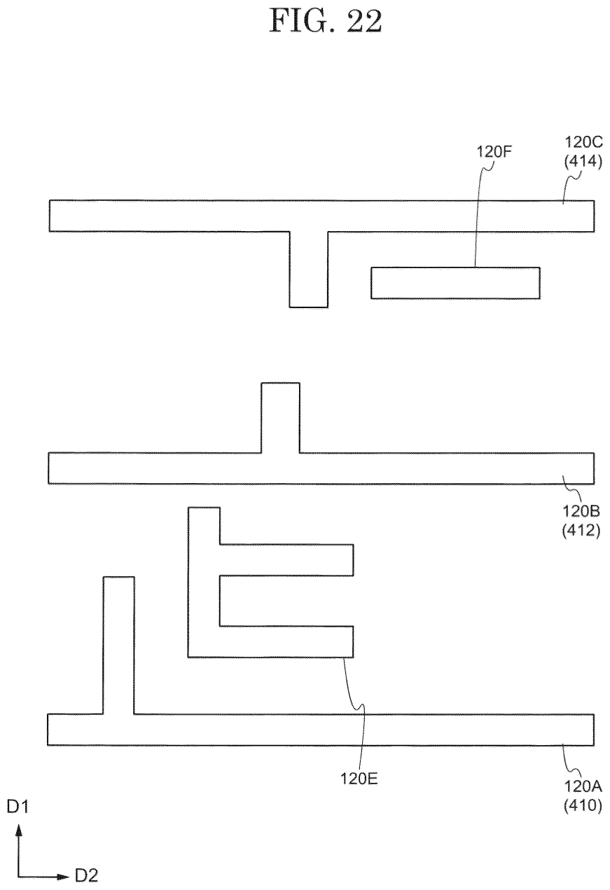

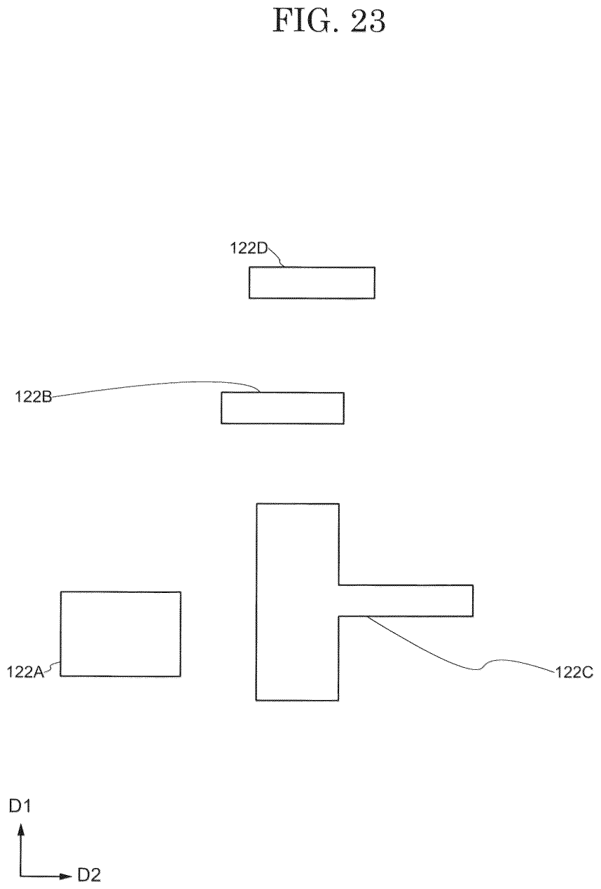

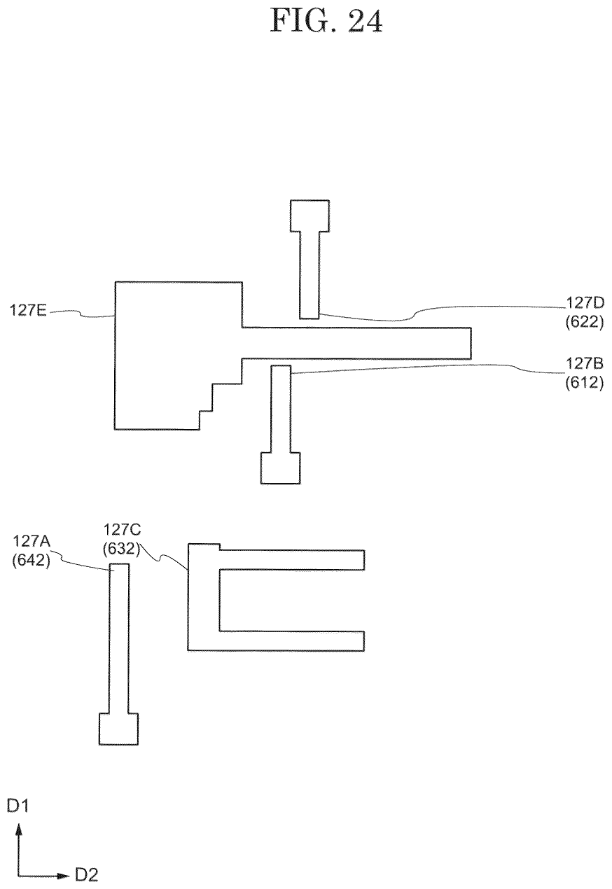

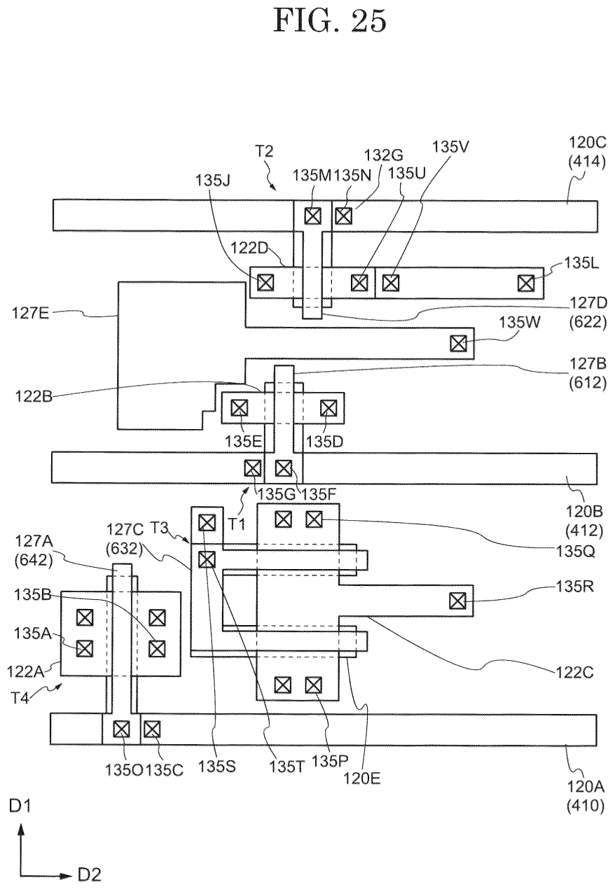

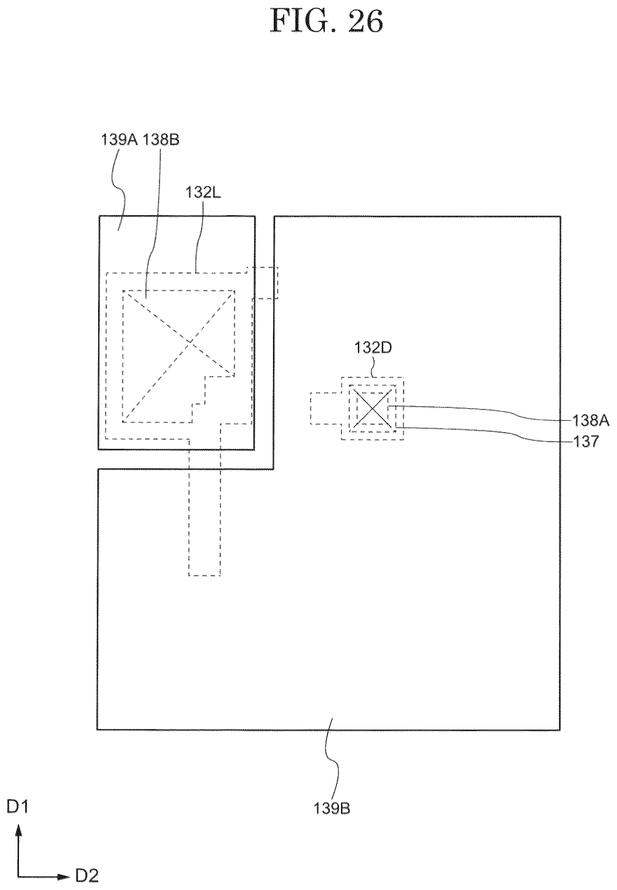

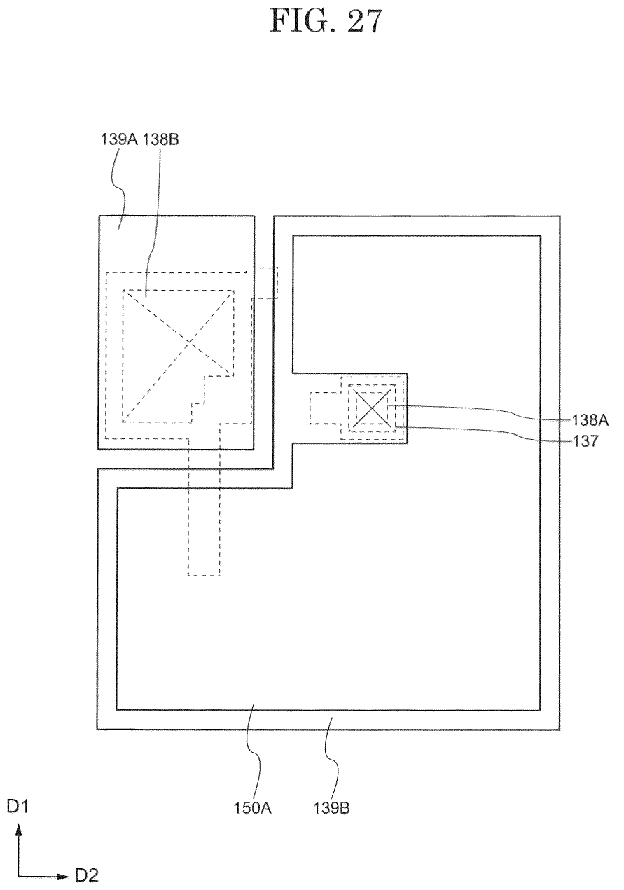

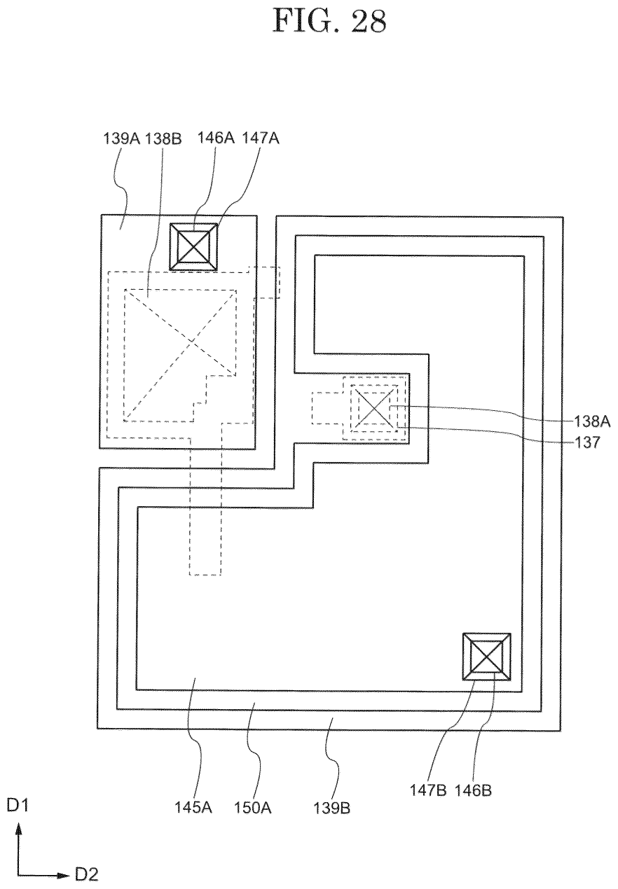

In order to make each layer easier to understand, FIG. 22 is a figure showing the layout of the conductive layer 120, FIG. 23 is a figure showing a layout of the conductive layer 122, FIG. 24 is a figure showing a layout of the gate electrode 127, FIG. 25 is a figure showing a layout in which the conductive layer 120, the oxide semiconductor layer 122, the conductive layer 132, the gate electrode 127, and the opening 135 overlap each other, FIG. 26 is a figure showing a layout in which the conductive layer 132L, the openings 138A and 138B, the opening 137, and the conductive layers 139A and 139B overlap each other, and FIG. 27 shows a layout in which the conductive layer 132L, the openings 138A and 138B, the opening 137, the conductive layers 139A and 139B, and the light emitting diode 150A overlap each other, and FIG. 28 is a diagram showing a layout in which the conductive layer 132L, the openings 138A and 138B, the opening 137, the conductive layers 139A and 139B, the light emitting diode 150A, then openings 146A and 146B, and the openings 147A and 147B overlap each other.

As shown in FIG. 20 and FIG. 22, the conductive layer 120 includes the conductive layers 120A (the read signal line 410), 120B (the data transfer signal line 412), 120C (the reset signal line 414), 120E, and 120F. The conductive layers 120A, 120B, 120C, 120E, and 120F are provided in the same layer. The conductive layers 120A, 120B, 120C, 120E, and 120F are spaced apart from each other. The pixel according to the third embodiment does not include the conductive layer 120D and includes the conductive layer 120F as compared with the pixel 502 according to the first embodiment.

As shown in FIG. 20 and FIG. 23, the oxide semiconductor layer 122 includes the oxide semiconductor layers 122A, 122B, 122C, and 122D as in the oxide semiconductor layer 122 of the pixel 502 according to the first embodiment. The oxide semiconductor layers 122A, 122B, 122C, and 122D are provided in the same layer. The oxide semiconductor layers 122A, 122B, 122C, and 122D are spaced apart from each other.

As shown in FIG. 20 and FIG. 24, the gate electrode 127 includes the gate electrodes 127A (the gate electrode 642), 127B (the gate electrode 612), 127C, 127D (the gate electrode 622), and 127E. As described in (13) above, the gate electrode 127E functions as the first electrode 32, and the drive voltage VPP is supplied. The gate electrodes 127A, 127B, 127C, 127D, and 127E are provided in the same layers. The gate electrodes 127A, 127B, 127C, 127D, and 127E are spaced apart from each other.

As shown in FIG. 20 and FIG. 25, the openings 135 include the openings 135A to 135G, 135J, and 135L to 135V. The openings 135 does not include the openings 135H and 1351. The opening 135 may pass through the insulating layer 128, may pass through the insulating layer 128 and the gate insulating layer 125, and may pass through the insulating layer 128, the gate insulating layer 125, and the insulating layer 121. As shown in FIG. 20, the conductive layers 132 includes the conductive layers 132A to 132G, and 132I to 132L. The conductive layers 132A to 132G, and 132I to 132L are provided in the same layer. The conductive layers 132A to 132G, and 132I to 132L are spaced apart from each other.

As shown in FIG. 21 and FIG. 26, the openings 138 includes the openings 138A and 138B. After the insulating layer 131 is formed, the opening 137 penetrates the insulating layer 131 to expose the conductive layer 132D. After the opening 137 exposes the conductive layer 132D, the insulating layer 136 is formed. The opening 138A penetrates the insulating layer 136 to expose the conductive layer 132D. The opening 138B penetrates the insulating layer 136 to expose the insulating layer 131. The conductive layer 139 includes the conductive layers 139A and 139B. The conductive layers 139A and 139B are provided in the same layer, and the conductive layers 139A and 139B are spaced apart from each other. The insulating layer 131 sandwiched between the conductive layer 139A and the conductive layer 132L, the conductive layer 139A, and the conductive layer 132L form the capacitive element SC3. The conductive layer 139B is electrically connected to the conductive layer 132D via the opening 137 and the opening 138A.

As shown in FIG. 21 and FIG. 27, the light emitting diode 150 includes the light emitting diode 150A. As shown in FIG. 21 and FIG. 28, the openings 146 include the openings 146A and 146B, and the openings 147 include openings 147A and 147B. The opening 146 passes through the insulating layer 141 and the opening 147 passes through the insulating layer 151. As shown in FIG. 21, the conductive layer 149 includes the conductive layer 149A, and the conductive layer 148 includes the conductive layer 148A. The conductive layer 149 contacts the conductive layer 148 and covers the conductive layer 148.

### [3-3. Configuration of Capacitive Element CS2 and Reset Transistor T2 of Pixel 502]

Next, referring to FIG. 20, FIG. 22 to FIG. 25, FIG. 29, and FIG. 30, configurations of the capacitive element CS2 and the reset transistor T2 according to the third embodiment will be described. The same or similar configurations as those in FIG. 1 to FIG. 19 will be described as necessary.

The end face of the pixel 502 according to the third embodiment shown in FIG. 29 is an end face along the conductive layer 132A (the output signal line 420), the conductive layer 132L, the gate electrode 127E, the opening 135J, the oxide semiconductor layer 122D, the conductive layer 120C, the gate electrode 127D (the gate electrode 622), the conductive layer 132K, the opening 135U, the opening 135V, the conductive layer 120F, the conductive layer 132F (the drive power supply line PVDD), the opening 135L, and the conductive layer 132I (the reset potential line SVR), as an example of the end face of the capacitive element CS2 and the end face of the reset transistor T2.

The end face of the pixel 502 according to the third embodiment shown in FIG. 30 is an end face of a region in which the end face shown in FIG. 29 is translated along the first direction D1, and is an end face along the conductive layer 132A (the output signal line 420), the conductive layer 132L, the gate electrode 127E, the conductive layer 132F (the drive power supply line PVDD), the opening 135W, and the conductive layer 132I (the reset potential line SVR).

As shown in FIG. 20, the capacitive element CS2 according to the third embodiment has a configuration in which the gate electrode 127E and the conductive layers 132L overlap each other in a plan view. Further, as shown in FIG. 29 and FIG. 30, the insulating layer 128 is sandwiched between the gate electrode 127E and the conductive layer 132L. Further, as shown in FIG. 29, the conductive layer 132L is electrically connected to the oxide semiconductor layer 122D through the opening 135J that penetrates the insulating layer 128 and the gate insulating layer 125 and exposes the oxide semiconductor layer 122D. Further, as shown in FIG. 30, the conductive layer 132F (the drive power supply line PVDD) is electrically connected to the gate electrode 127E through the opening 135J that penetrates the insulating layer 128 and exposes the gate electrode 127E. That is, the capacitive element CS2 includes a capacitive element formed by the conductive layer 120D+120F and the oxide semiconductor layer 122E sandwiching the insulating layer 128 therebetween, and a capacitive element formed by the gate electrode 127E and the conductive layer 132L sandwiching the insulating layer 128 therebetween. In this case, the gate electrode 127E is electrically connected to the conductive layer 132F (the drive power supply line PVDD), and the gate electrode 127E is supplied with the drive voltage VPP from the conductive layer 132F (the drive power supply line PVDD).

As shown in FIG. 20, FIG. 23, or FIG. 29, the reset transistor T2 according to the third embodiment includes the same configuration as the reset transistor T2 according to the first embodiment. For example, the oxide semiconductor layer 122B in a region overlapping the gate electrode 127D (the gate electrode 622) in a plan view functions as the semiconductor layer (channels) of the reset transistor T2, and is switched between the conductive state and the non-conductive state in accordance with the voltage supplied to the gate electrode 127D. That is, the oxide semiconductor layer 122D in a region not overlapping the gate electrode 127D in a plan view functions as the conductive layer of the reset transistor T2, and is the first electrode 624 and the second electrode 626. Further, in the reset transistor T2 according to the third embodiment, a part of the oxide semiconductor layer 122D in the region not overlapping the gate electrode 127D in the plan view, which functions as the second electrode 34 of the capacitive element SC2, is electrically connected to the conductive layer 132L via the opening 135J. On the other hand, in the reset transistor T2 according to the third embodiment, a part of the oxide semiconductor layer 122D in the region not overlapping the gate electrode 127D in the plan view, which functions as the second electrode 32 of the capacitive element SC2, is electrically connected to the conductive layer 132I (the reset potential line SVR) via the opening 135U that exposes the oxide semiconductor layer 122D, the opening 135K that exposes the conductive layer 132K, the conductive layer 120F, and the opening 135L that exposes the conductive layer 120F.

### [3-4. Configuration of Capacitive Element CS3 and Photoelectric Conversion Element 110 of Pixel 502]

Next, referring to FIG. 20, FIG. 26 to FIG. 28, and FIG. 31, a configuration of the capacitive element CS3 and a configuration of the photoelectric conversion element 110 according to the third embodiment will be described. Configurations that are the same as or similar to those in FIG. 1 to FIG. 30 are described as necessary.

The end face of the pixel 502 according to the third embodiment shown in FIG. 31 is an end face along the conductive layer 149A, the conductive layer 148A, the conductive layer 139A, the conductive layer 132L, the opening 138A, the conductive layer 139B, the light emitting diode 150A, the conductive layer 145A, and the conductive layer 149A and the conductive layer 148A as an exemplary end face of the capacitive element CS3 and the photoelectric conversion element 110.

As shown in FIG. 21, the capacitive element CS3 according to the third embodiment has a configuration in which the conductive layer 139A covers the conductive layer 132L and the conductive layer 139A overlaps the conductive layer 132L in a plan view. That is, an area of the conductive layer 139A is larger than an area of the conductive layer 132L. As shown in FIG. 31, the insulating layer 131 is sandwiched between the conductive layer 132L and the conductive layer 139A. The conductive layer 132L is electrically connected to the oxide semiconductor layer 122D functioning as the second electrode 44 of the capacitive element SC3, and when the reset transistor T2 becomes conductive, the reset voltage VRES is supplied to the conductive layer 132L. Further, the conductive layer 139A is electrically connected to the conductive layer 132L through the opening 146A that penetrates the insulating layer 141 and exposes the conductive layer 132L and the opening 147A that penetrates the insulating layer 151. The conductive layer 139A functions as the first electrodes 42 of the capacitive element SC3. As shown in FIG. 19, the first electrode 42 is electrically connected to the reference potential line PVSS, and the reference voltage VSS is supplied. That is, the conductive layer 139A is electrically connected to the reference potential line PVSS, and the reference voltage VSS is supplied thereto.

As shown in FIG. 21, FIG. 26 to FIG. 28, or FIG. 31, the photoelectric conversion element 110 according to the third embodiment includes the same configuration as the photoelectric conversion element 110 according to the first embodiment. For example, in a plan view, the conductive layer 145A overlaps the light emitting diode 150A, the light emitting diode 150A overlaps the conductive layer 139B, an area of the conductive layer 139B is larger than an area of the light emitting diode 150A, and the area of the light emitting diode 150A is larger than an area of the conductive layer 145A. The conductive layer 149A covers the conductive layer 148A, and the conductive layer 149A overlaps the conductive layer 148A. That is, an area of the conductive layer 149A is larger than an area of the conductive layer 148A. The conductive layer 149A is electrically connected to the conductive layer 145A through the opening 146B that penetrates the insulating layer 141 and exposes the conductive layer 145A and the opening 147B that penetrates the insulating layer 151.

Referring also to FIG. 5, FIG. 19, FIG. 20, or FIG. 21, the conductive layer 139B is electrically connected to the conductive layer 132D via the opening 147A and the opening 138A. The conductive layer 139B corresponds to the second electrode 14 of the photoelectric conversion element 110, and the conductive layer 139B is electrically connected to the node N1, the first electrode 614 of the data transfer transistor T1, and the second electrode 24 of the capacitive element SC1.

Referring to FIG. 20 or FIG. 21, a region where the conductive layer 132L in the pixel 502 of the solid-state imaging device according to the third embodiment overlaps the conductive layer 139B (lower electrode) of the photoelectric conversion element 110 is a small region around the periphery including a region where the conductive layer 132L overlaps the openings 135S and 135T. Further, although the conductive layer 139B (the lower electrode) overlaps the node N1, as described above, there are few regions where the conductive layer 139B (the lower electrode) overlaps the node N2. Therefore, the parasitic capacitance due to coupling with the node N1 is hardly added to the node N2.

Therefore, the pixel 502 of the solid-state imaging device according to the third embodiment includes a configuration capable of suppressing the parasitic capacitance caused by the superimposition of the node N2 and the conductive layers 139B from being added to the node N2, and includes a configuration capable of suppressing the parasitic capacitance caused by the coupling with the node N1. In addition, since the pixel 502 of the solid-state imaging device according to the third embodiment includes the capacitive element SC3, capacitance can be increased from CSss to CSss+CSst. As a consequence, it is possible to increase capacitance between the node N2 and the gate electrode 127E to which the conductive layers 132F (the drive power supply lines PVDD) are connected, and to reduce parasitic capacitance between the node N2 and the node N1.

For example, as shown in Table 2, in the conventional solid-state imaging device, a proportion of the capacitance added to the node N2 is approximately 14% due to the capacitance caused by the node N1, and approximately 68% due to the drive power supply line PVDD and the reference potential line PVSS. Further, as shown in Table 2, in the solid-state imaging device 100 of the present invention, the proportion of the capacitance added to the node N2 is approximately 2% due to the capacitance caused by the node N1, and approximately 92% due to the drive power supply line PVDD and the reference potential line PVSS. Therefore, in the configurations of the capacitance element SC2 and the capacitance element SC3 of the solid-state imaging device 100, the capacitance value caused by the node N1 is smaller than the configuration of the capacitance element SC2 of the conventional solid-state imaging device, and the capacitance value caused by the drive power supply line PVDD and the reference potential line PVSS is larger than the configuration of the capacitance element SC2 of the conventional solid-state imaging device.

TABLE 2

| | | Capacitance value added to |
|---|---|---|
| | Capacitance value added to | node N2 of solid-state |
| | node N2 of conventional | imaging device of the present |
| | solid-state imaging device | invention |
| Node N1 | 14% | 2% |
| Drive power | 68% | 92% |
| supply line | | |
| PVDD | | |

As a result, Similar to the solid-state imaging device 100 according to the first embodiment, the solid-state imaging device according to the third embodiment has a configuration capable of reducing the parasitic capacitance due to coupling, since it has a configuration capable of increasing the proportion of the capacitance value of the power supply voltage, it is possible to suppress the influence of the coupling and to suppress the influence of noise. Therefore, Similar to the solid-state imaging device 100 according to the first embodiment, the solid-state imaging device according to the third embodiment has a long-term highly reliable configuration.

Various configurations of the detecting device (the solid-state imaging device) exemplified as one of the embodiments of the present invention can be appropriately combined as long as they do not conflict with each other. Further, various configurations of the detecting device (the solid-state imaging device) exemplified as one of the embodiments of the present invention can be replaced as appropriate as long as they do not conflict with each other. On the basis of the detecting device (the solid-state imaging device) disclosed in the present specification and the drawings, any addition, deletion, or design change of components by a person skilled in the art, or addition, omission, or change of conditions of a process, is included in the scope of the present invention as long as the essence of the present invention is maintained.

It is to be understood that the present invention provides other effects that are different from the effects provided by the aspects of the embodiments disclosed herein, and those that are obvious from the description herein or that can be easily predicted by a person skilled in the art.

What is claimed is:

1. A detecting device comprising:
a photoelectric conversion element electrically connected to a first node;
a first transistor including a first oxide semiconductor layer and electrically connected between the first node and a second node;
a second transistor including a second oxide semiconductor layer provided in the same layer as the first oxide semiconductor layer and connected between the second node and a reset potential line to which a constant voltage is supplied; and
a first capacitance element including a first conductive layer stacked under the same layer as the first oxide semiconductor layer and electrically connected to a power supply line that supplies a power supply voltage, an electrode layer stacked on the same layer as the first oxide semiconductor layer and electrically connected to the second node, and a second conductive layer stacked on the electrode layer and electrically connected to the power supply line.

2. The detecting device according to claim 1,
wherein, in a plan view, the second conductive layer overlaps the electrode layer, and the electrode layer overlaps the first conductive layer.

3. The detecting device according to claim 1,
wherein the second conductive layer is provided in the same layer as the power supply line and the reset potential line, and
the second conductive layer, the power supply line, and the reset potential line are arranged apart from each other.

4. The detecting device according to claim 1,
wherein the first transistor includes a gate electrode and a lower gate electrode,
in an end view, the first oxide semiconductor layer is provided between the lower gate electrode and the gate electrode, the lower gate electrode is arranged in the same layer as the first conductive layer, the gate electrode is stacked on the lower gate electrode and arranged in the same layer as the electrode layer,
in a plan view, the first oxide semiconductor layer, the gate electrode, and the lower gate electrode overlap each other,
the first oxide semiconductor layer overlapping the gate electrode is a channel, and the first oxide semiconductor layer other than the channel includes a first electrode and a second electrode of the first oxide semiconductor layer, and
the first electrode is electrically connected to the electrode layer, and the second electrode is electrically connected to the first node.

5. The detecting device according to claim 1, wherein
the second transistor includes a gate electrode and a lower gate electrode,
in an end view, the second oxide semiconductor layer is provided between the lower gate electrode and the gate electrode, the lower gate electrode is arranged in the same layer as the first conductive layer, the gate electrode is stacked on the lower gate electrode and arranged in the same layer as the electrode layer,
in a plan view, the second oxide semiconductor layer, the gate electrode, and the lower gate electrode overlap each other, the second oxide semiconductor layer overlapping the gate electrode is a channel, and the second oxide semiconductor layer other than the channel includes a first electrode and a second electrode of the second oxide semiconductor layer.

6. The detecting device according to claim 1, further comprising a third transistor,
wherein the third transistor includes a third oxide semiconductor layer, a gate electrode, and a lower gate electrode,
the third oxide semiconductor layer is arranged in the same layer as the first oxide semiconductor layer,
in an end view, the third oxide semiconductor layer is provided between the lower gate electrode of the third transistor and the gate electrode of the third transistor, the lower gate electrode of the third transistor is arranged in the same layer as the first conductive layer,
the gate electrode of the third transistor is arranged on the second conductive layer as the same conductive layer that also serves as the electrode layer,
in a plan view, the third oxide semiconductor layer, the gate electrode of the third transistor, and the lower gate electrode of the third transistor overlap each other,
the third oxide semiconductor layer overlapping the gate electrode of the third transistor is a channel, and the third oxide semiconductor layer other than the channel includes a first electrode and a second electrode of the third transistor,
the gate electrode of the third transistor is electrically connected to a second node, the first electrode of the third transistor is electrically connected to a third node, and the second electrode of the third transistor is electrically connected to the power supply line.

7. The detecting device according to claim 6, further comprising a fourth transistor,
wherein the fourth transistor includes a fourth oxide semiconductor layer, a gate electrode, and a lower gate electrode,
the fourth oxide semiconductor layer is arranged in the same layer as the first oxide semiconductor layer,
in an end view, the fourth oxide semiconductor layer is provided between the lower gate electrode of the fourth transistor and the gate electrode of the fourth transistor, the lower gate electrode of the fourth transistor is arranged in the same layer as the first conductive layer,
the gate electrode of the fourth transistor is arranged in the same layer as the electrode layer,
in a plan view, the fourth oxide semiconductor layer, the gate electrode of the fourth transistor, and the lower gate electrode of the fourth transistor overlap each other,
the fourth oxide semiconductor layer overlapping the gate electrode of the fourth transistor is a channel, and the fourth oxide semiconductor layer other than the channel includes a first electrode and a second electrode of the fourth transistor,
the gate electrode of the fourth transistor is electrically connected to a control signal line that controls an on state and an off state of the fourth transistor, the second electrode of the fourth transistor is electrically connected to the third node, and the first electrode of the fourth transistor is electrically connected to an output signal line for outputting a voltage detected by the detecting device.

8. A detecting device comprising:
a photoelectric conversion element electrically connected to a first node;
a first transistor including a first oxide semiconductor layer electrically connected between the first node and a second node;
a second transistor including a second oxide semiconductor layer provided in the same layer as the first oxide semiconductor layer and connected between the second node and a reset potential line to which a constant voltage is supplied; and
a first capacitance element including a first conductive layer stacked under the same layer as the first oxide semiconductor layer and electrically connected to a power supply line that supplies a power supply voltage, a third oxide semiconductor layer arranged in the same layer as the first oxide semiconductor layer and electrically connected to the second node, and a second conductive layer stacked on the third oxide semiconductor layer and electrically connected to the power supply line.

9. The detecting device according to claim 8,
wherein, in a plan view, the second conductive layer overlaps the third oxide semiconductor layer, and the third oxide semiconductor layer overlaps the first conductive layer.

10. The detecting device according to claim 8,
wherein the second conductive layer is provided in the same layer as the power supply line and the reset potential line, and
the second conductive layer, the power supply line, and the reset potential line are arranged separately from each other.

11. The detecting device according to claim 8,
wherein the first transistor includes a gate electrode and a lower gate electrode,
in an end view, the first oxide semiconductor layer is provided between the lower gate electrode and the gate electrode, the lower gate electrode is arranged in the same layer as the first conductive layer, and the gate electrode is stacked on the lower gate electrode,
in a plan view, the first oxide semiconductor layer, the gate electrode, and the lower gate electrode overlap each other, and
the first oxide semiconductor layer, the second oxide semiconductor layer, and the third oxide semiconductor layer are arranged on the first conductive layer as a single member.

12. The detecting device according to claim 8,
wherein the second transistor includes a gate electrode and a lower gate electrode,
in an end view, the second oxide semiconductor layer is provided between the lower gate electrode and the gate electrode, the lower gate electrode is arranged in the same layer as the first conductive layer, and the gate electrode is stacked on the lower gate electrode,
in a plan view, the second oxide semiconductor layer, the gate electrode, and the lower gate electrode overlap each other, and
the first oxide semiconductor layer, the second oxide semiconductor layer, and the third oxide semiconductor layer are arranged as a single member on the first conductive layer.

13. The detecting device according to claim 8, further comprising a third transistor,
wherein the third transistor includes a fourth oxide semiconductor layer, a gate electrode, and a lower gate electrode,
the fourth oxide semiconductor layer is arranged on the same layer as the first oxide semiconductor layer, the second oxide semiconductor layer, and the third oxide semiconductor layer,
in the end view, the fourth oxide semiconductor layer is provided between the lower gate electrode of the third transistor and the gate electrode of the third transistor, and the lower gate electrode of the third transistor is arranged in the same layer as the first conducting layer,
the gate electrode of the third transistor is electrically connected to the second node and the second oxide semiconductor layer and is arranged above the second oxide semiconductor layer,
in a plan view, the fourth oxide semiconductor layer, the gate electrode of the third transistor and the lower gate electrode of the third transistor overlap each other,
the fourth oxide semiconductor layer overlapping the gate electrode of the third transistor is a channel, and the fourth oxide semiconductor layer other than the channel includes a first electrode and a second electrode of the third transistor,
the first electrode of the third transistor is electrically connected to a third node, and the second electrode of the third transistor is electrically connected to the power line, and
the first oxide semiconductor layer, the second oxide semiconductor layer, and the third oxide semiconductor layer are arranged on the first conductive layer as a single member.

14. The detecting device according to claim 13, further comprising a fourth transistor;
wherein the fourth transistor includes a fifth oxide semiconductor layer, a gate electrode, and a lower gate electrode,
the fifth oxide semiconductor layer is disposed in the same layer as the first oxide semiconductor layer, the second oxide semiconductor layer, the third oxide semiconductor layer, and the fourth oxide semiconductor layer,
in an end view, the fourth oxide semiconductor layer is provided between the lower gate electrode of the fourth transistor and the gate electrode of the fourth transistor, the lower gate electrode of the fourth transistor is disposed in the same layer as the first conductive layer,
the gate electrode of the fourth transistor is disposed in the same layer as the gate electrode of the third transistor,
in a plan view, the fifth oxide semiconductor layer, the gate electrode of the fourth transistor, and the lower gate electrode of the fourth transistor overlap,
the fifth oxide semiconductor layer overlapping the gate electrode of the fourth transistor is a channel, and the fifth oxide semiconductor layer includes a first electrode and a second electrode of the fourth transistor other than the channel, and
the gate electrode of the fourth transistor is electrically connected to a control signal line that controls an on state and an off state of the fourth transistor, the second electrode of the fourth transistor is electrically connected to the third node, and the first electrode of the fourth transistor is electrically connected to an output signal line for outputting a voltage detected by the detecting device.

15. A detecting device comprising:
a photoelectric conversion element electrically connected to a first node;
a first transistor including a first oxide semiconductor layer electrically connected between the first node and a second node;
a second transistor provided in the same layer as the first oxide semiconductor layer and including a second oxide semiconductor layer connected between the second node and a reset potential line to which a constant voltage is supplied;
a first capacitance element including a first conductive layer stacked on the same layer and electrically connected to a power supply line to which a power supply voltage is supplied, and a second conductive layer stacked on the first conductive layer and electrically connected to the second node; and
a second capacitance element including a third conductive layer arranged on the second conductive layer and electrically connected to a reference potential line to which a reference voltage is supplied.

16. The detecting device according to claim 15,
wherein the first capacitance element includes a first electrode and a second electrode,
the second capacitance element includes a first electrode and a second electrode,
the photoelectric conversion element includes a first electrode and a second electrode provided below the first electrode,
the first electrode of the first capacitance element is the first conductive layer, the first electrode of the second capacitance element is the third conductive layer, the second conductive layer serves as both the second electrode of the first capacitance element and the second electrode of the second capacitance element,
in a plan view, the third conductive layer overlaps the second conductive layer, the second conductive layer overlaps the first conductive layer, the first electrode of the photoelectric conversion element overlaps the second electrode of the photoelectric conversion element, and the first electrode and the second electrode of the photoelectric conversion element are arranged at a distance from the third conductive layer and the second conductive layer, and
in an end view, the second conductive layer is provided in the same layer as the power supply line and the reset potential line, the second conductive layer, the power supply line, and the reset potential line are arranged at a distance from each other, the second electrode of the photoelectric conversion element is provided in the same layer as the third conductive layer, and the second electrode of the photoelectric conversion element and the third conductive layer are arranged at a distance from each other.

17. The detecting device according to claim 15,
wherein the first transistor includes a gate electrode,
in an end view, the gate electrode is provided on the first oxide semiconductor layer, and the gate electrode is arranged in the same layer as the first conductive layer,
in a plan view, the first oxide semiconductor layer and the gate electrode overlap each other,
the first oxide semiconductor layer overlapping the gate electrode is a channel, and the first oxide semiconductor layer other than the channel includes a first electrode and a second electrode of the first oxide semiconductor layer, and
the first electrode is electrically connected to the second conductive layer, and the second electrode is electrically connected to the first node.

18. The detecting device according to claim 15,
wherein the second transistor includes a gate electrode and a lower gate electrode,
in an end view, the gate electrode is provided on the second oxide semiconductor layer, and the gate electrode is arranged in the same layer as the first conductive layer,
in a plan view, the second oxide semiconductor layer and the gate electrode overlap each other,
the second oxide semiconductor layer overlapping the gate electrode is a channel, the second oxide semiconductor layer other than the channel includes a first electrode and a second electrode of the second oxide semiconductor layer, and
the first electrode is electrically connected to the second node, and the second electrode is electrically connected to the reset potential line.

19. The detecting device according to claim 15, further comprising a third transistor;
wherein the third transistor includes a third oxide semiconductor layer and a gate electrode,
the third oxide semiconductor layer is arranged in the same layer,
in an end view, the gate electrode is provided on the third oxide semiconductor layer,
the gate electrode of the third transistor is electrically connected to the second conductive layer,
in a plan view, the third oxide semiconductor layer and the gate electrode of the third transistor overlap each other,
the third oxide semiconductor layer overlapping the gate electrode of the third transistor is a channel, and the third oxide semiconductor layer other than the channel includes a first electrode and a second electrode of the third transistor,
the first electrode of the third transistor is electrically connected to a third node, and the second electrode of the third transistor is electrically connected to the power supply line.

20. The detecting device according to claim 19, further comprising a fourth transistor,
wherein the fourth transistor includes a fourth oxide semiconductor layer and a gate electrode,
the fourth oxide semiconductor layer is arranged in the same layer,
in an end view, the gate electrode is provided on the fourth oxide semiconductor layer,
the gate electrode of the fourth transistor is arranged in the same layer as the gate electrode of the third transistor,
in a plan view, the fourth oxide semiconductor layer and the gate electrode of the fourth transistor overlap each other,
the fourth oxide semiconductor layer overlapping the gate electrode of the fourth transistor is a channel, the fourth oxide semiconductor layer other than the channel includes a first electrode and a second electrode of the fourth transistor,
the gate electrode of the fourth transistor is electrically connected to a control signal line that controls an on state and an off state of the fourth transistor, and
the second electrode of the fourth transistor is electrically connected to the third node, and the first electrode of the fourth transistor is electrically connected to an output signal line for outputting a voltage detected by the detecting device.
